(19) United States
(12) Patent Application Publication
(10) Pub. No.: US 2025/0017072 A1
(43) Pub. Date: Jan. 9, 2025

(54) DISPLAY DEVICE, DISPLAY MODULE, ELECTRONIC DEVICE, AND METHOD FOR FABRICATING DISPLAY DEVICE

(71) Applicant: Semiconductor Energy Laboratory Co., Ltd., Atsugi-shi, Kanagawa-ken (JP)

(72) Inventors: Shinya SASAGAWA, Chigasaki (JP); Ryota HODO, Atsugi (JP); Kentaro SUGAYA, Isehara (JP); Yuichi YANAGISAWA, Atsugi (JP)

(21) Appl. No.: 18/698,963

(22) PCT Filed: Oct. 14, 2022
(86) PCT No.: PCT/IB2022/059834

§ 371 Date: Apr. 5, 2024

(30) Foreign Application Priority Data
Oct. 27, 2021 (JP) 2021-175199

(51) Int. Cl. H10K 59/38; H10K 50/19

(52) U.S. Cl. CPC H10K 59/38; H10K 50/19

(57) ABSTRACT

A high-resolution display device is provided. A first light-emitting device and a second light-emitting device are included over an insulating surface. A first sidewall insulating layer is in contact with a side surface of a first pixel electrode included in the first light-emitting device, and a second sidewall insulating layer is in contact with a side surface of a second pixel electrode included in the second light-emitting device. The first light-emitting device overlaps with a first coloring layer, and the second light-emitting device overlaps with a second coloring layer that transmits light of a color different from a color of light transmitted through the first coloring layer. The first light-emitting device and the second light-emitting device share a common electrode. A first layer included in the first light-emitting device, a second layer included in the second light-emitting device, and a material layer positioned over the top surface of an insulating layer and positioned between the first sidewall insulating layer and the second sidewall insulating layer contain the same light-emitting material and are apart from one another.

### TECHNICAL FIELD

One embodiment of the present invention relates to a display device, a display module, and an electronic device. One embodiment of the present invention relates to a method for fabricating a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

Recent display devices have been expected to be applied to a variety of uses. Usage examples of large-sized display devices include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display devices have been required. As devices requiring high-resolution display devices, for example, devices for virtual reality (VR), augmented reality (AR), substitutional reality (SR), or mixed reality (MR) have been actively developed.

Light-emitting apparatuses including light-emitting devices (also referred to as light-emitting elements) have been developed as display devices, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display devices.

Patent Document 1 discloses a display device using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a high-resolution display device. Another object of one embodiment of the present invention is to provide a high-definition display device. Another object of one embodiment of the present invention is to provide a highly reliable display device.

Another object of one embodiment of the present invention is to provide a method for fabricating a high-resolution display device. Another object of one embodiment of the present invention is to provide a method for fabricating a high-definition display device. Another object of one embodiment of the present invention is to provide a method for fabricating a highly reliable display device. Another object of one embodiment of the present invention is to provide a method for fabricating a display device with high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device including a first light-emitting device, a second light-emitting device, an insulating layer, a first sidewall insulating layer, a second sidewall insulating layer, a first coloring layer, and a second coloring layer. The first light-emitting device includes a first pixel electrode over the insulating layer, a first layer over the first pixel electrode, and a common electrode over the first layer. The second light-emitting device includes a second pixel electrode over the insulating layer, the first layer over the second pixel electrode, and the common electrode over the first layer. The first sidewall insulating layer is in contact with a side surface of the first pixel electrode. The second sidewall insulating layer is in contact with a side surface of the second pixel electrode. The first coloring layer overlaps with the first light-emitting device. The second coloring layer overlaps with the second light-emitting device. The second coloring layer and the first coloring layer transmit light of different colors. The first layer contains a first light-emitting material that emits blue light and a second light-emitting material that emits light with a longer wavelength than blue light. The first layer includes a portion in contact with a top surface of the insulating layer between the first sidewall insulating layer and the second sidewall insulating layer.

Another embodiment of the present invention is a display device including a first light-emitting device, a second light-emitting device, a material layer, an insulating layer, a first sidewall insulating layer, a second sidewall insulating layer, a first coloring layer, and a second coloring layer. The first light-emitting device includes a first pixel electrode over the insulating layer, a first layer over the first pixel electrode, and a common electrode over the first layer. The second light-emitting device includes a second pixel electrode, a second layer over the second pixel electrode, and the common electrode over the second layer. The first sidewall insulating layer is in contact with a side surface of the first pixel electrode. The second sidewall insulating layer is in contact with a side surface of the second pixel electrode. The material layer is in contact with a top surface of the insulating layer and positioned between the first sidewall insulating layer and the second sidewall insulating layer. The first coloring layer overlaps with the first light-emitting device. The second coloring layer overlaps with the second light-emitting device. The second coloring layer and the first coloring layer transmit light of different colors. The first layer, the second layer, and the material layer include the same light-emitting material and are apart from one another.

The first layer preferably contains a first light-emitting material that emits blue light and a second light-emitting material that emits light with a longer wavelength than blue light.

The material layer is preferably in contact with at least one of a side surface of the first sidewall insulating layer and a side surface of the second sidewall insulating layer.

It is preferable that the first sidewall insulating layer be further in contact with a side surface and the top surface of the insulating layer and the second sidewall insulating layer be further in contact with a side surface and the top surface of the insulating layer.

The shortest distance between the first sidewall insulating layer and the second sidewall insulating layer is preferably less than 10 μm.

The shortest distance between the first sidewall insulating layer and the second sidewall insulating layer is preferably less than or equal to 1 μm.

The first sidewall insulating layer preferably contains an inorganic insulating material.

Another embodiment of the present invention is a display module including the display device having any of the above structures and is, for example, a display module provided with a connector such as a flexible printed circuit (hereinafter referred to as an FPC) or a TCP (Tape Carrier Package), or a display module on which an integrated circuit (IC) is mounted by a COG (Chip On Glass) method, a COF (Chip On Film) method, or the like.

Another embodiment of the present invention is an electronic device including the above display module and at least one of a housing, a battery, a camera, a speaker, and a microphone.

Another embodiment of the present invention is a method for fabricating a display device including the steps of: forming a conductive film over an insulating surface; processing the conductive film to form a first pixel electrode and a second pixel electrode; forming an insulating film covering the first pixel electrode and the second pixel electrode; processing the insulating film to form a first sidewall insulating layer in contact with a side surface of the first pixel electrode and a second sidewall insulating layer in contact with a side surface of the second pixel electrode and to expose a top surface of the first pixel electrode and a top surface of the second pixel electrode; forming a first layer in contact with the top surface of the first pixel electrode, the top surface of the second pixel electrode, and the insulating surface; forming a common electrode in contact with the first layer; and arranging a first coloring layer overlapping with the first pixel electrode and a second coloring layer overlapping with the second pixel electrode over the common electrode. The first layer contains a first light-emitting material that emits blue light and a second light-emitting material that emits light with a longer wavelength than blue light.

Another embodiment of the present invention is a method for fabricating a display device including the steps of: forming a conductive film over an insulating surface; processing the conductive film to form a first pixel electrode and a second pixel electrode; forming an insulating film covering the first pixel electrode and the second pixel electrode; processing the insulating film to form a first sidewall insulating layer in contact with a side surface of the first pixel electrode and a second sidewall insulating layer in contact with a side surface of the second pixel electrode and to expose a top surface of the first pixel electrode and a top surface of the second pixel electrode; forming a first layer in contact with the top surface of the first pixel electrode, a second layer in contact with the top surface of the second pixel electrode, and a material layer in contact with the insulating surface in the same step; forming a common electrode in contact with the first layer and the second layer; and arranging a first coloring layer overlapping with the first pixel electrode and a second coloring layer overlapping with the second pixel electrode over the common electrode. The common electrode is preferably in contact with the material layer.

### Effect of the Invention

One embodiment of the present invention can provide a high-resolution display device. One embodiment of the present invention can provide a high-definition display device. One embodiment of the present invention can provide a highly reliable display device.

One embodiment of the present invention can provide a method for fabricating a high-resolution display device. One embodiment of the present invention can provide a method for fabricating a high-definition display device. One embodiment of the present invention can provide a method for fabricating a highly reliable display device. One embodiment of the present invention can provide a method for fabricating a display device with high yield.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view showing an example of a display device. FIG. 1B and FIG. 1C are cross-sectional views showing the example of the display device.

FIG. 2A to FIG. 2D are cross-sectional views showing examples of a display device.

FIG. 3A to FIG. 3C are cross-sectional views showing an example of a display device.

FIG. 4A to FIG. 4C are cross-sectional views showing examples of a display device.

FIG. 5A and FIG. 5B are cross-sectional views showing examples of a display device.

FIG. 6A to FIG. 6E are cross-sectional views showing an example of a method for fabricating a display device.

FIG. 7A to FIG. 7G are diagrams showing pixel examples.

FIG. 8A to FIG. 8I are diagrams showing pixel examples.

FIG. 9A and FIG. 9B are perspective views showing an example of a display device.

FIG. 10 is a cross-sectional view showing an example of a display device.

FIG. 11 is a cross-sectional view showing an example of a display device.

FIG. 12 is a cross-sectional view showing an example of a display device.

FIG. 13 is a cross-sectional view showing an example of a display device.

FIG. 14 is a cross-sectional view showing an example of a display device.

FIG. 15 is a cross-sectional view showing an example of a display device.

FIG. 16 is a perspective view showing an example of a display device.

FIG. 17A is a cross-sectional view showing an example of a display device. FIG. 17B and FIG. 17C are cross-sectional views showing examples of transistors.

FIG. 18A to FIG. 18D are cross-sectional views showing examples of a display device.

FIG. 19A to FIG. 19F are diagrams showing structure examples of light-emitting devices.

FIG. 20A to FIG. 20C are diagrams showing structure examples of light-emitting devices.

FIG. 21A to FIG. 21D are diagrams showing examples of electronic devices.

FIG. 22A to FIG. 22F are diagrams showing examples of electronic devices.

FIG. 23A to FIG. 23G are diagrams showing examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is applied to portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in drawings.

Note that the term “film” and the term “layer” can be interchanged with each other depending on the case or the circumstances. For example, the term “conductive layer” can be replaced with the term “conductive film”. As another example, the term “insulating film” can be replaced with the term “insulating layer”.

In this specification and the like, a device fabricated using a metal mask or an FMM (fine metal mask, high-resolution metal mask) may be referred to as a device having an MM (metal mask) structure. In addition, in this specification and the like, a device fabricated without using a metal mask or an FMM may be referred to as a device having an MML (metal maskless) structure.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

Note that in this specification and the like, step disconnection refers to a phenomenon in which a layer, a film, or an electrode is split because of the shape of the formation surface (e.g., a step).

### Embodiment 1

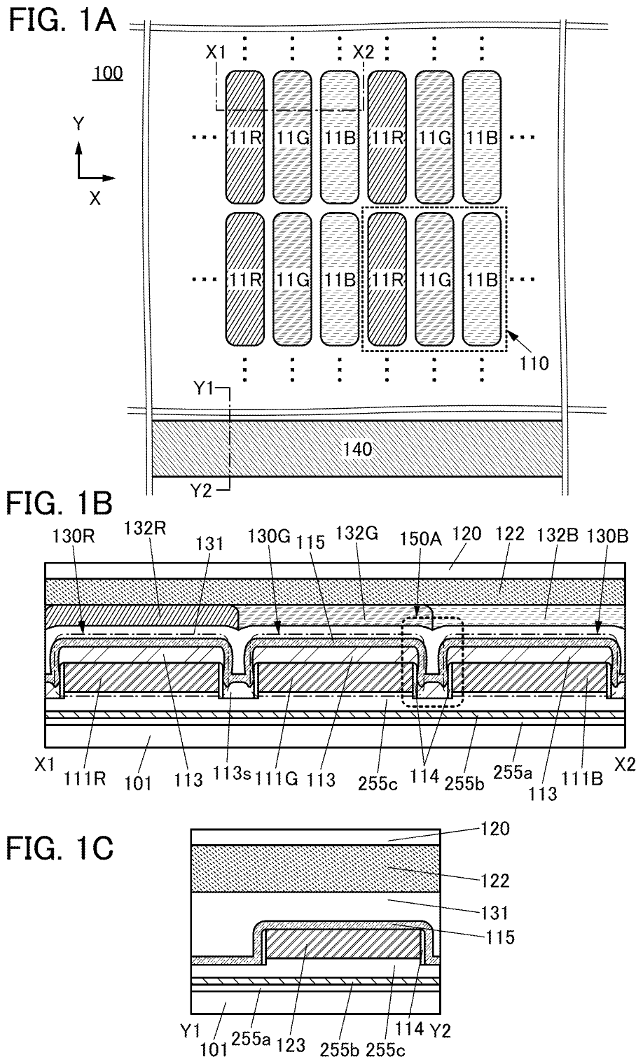

In this embodiment, a display device of one embodiment of the present invention is described with reference to FIG. 1 to FIG. 5.

A display device of one embodiment of the present invention includes a plurality of subpixels. The subpixels include light-emitting devices containing the same light-emitting material and coloring layers overlapping with the light-emitting devices. Coloring layers that transmit visible light of different colors are provided for the subpixels, whereby full-color display can be performed.

When light-emitting devices containing the same light-emitting material are used, a layer included in the light-emitting device other than a pixel electrode (e.g., a light-emitting layer) can be shared by a plurality of subpixels. Thus, the plurality of subpixels can share a continuous film. However, some of the layers included in the light-emitting device have relatively high conductivity. When the plurality of subpixels share the continuous film with high conductivity, leakage current might be generated between the subpixels. Particularly when the increase in resolution or aperture ratio of a display device reduces the distance between subpixels, the leakage current might become too large to ignore and cause a decrease in display quality of the display device, for example.

In view of the above, in the display device of one embodiment of the present invention, an EL layer shared by a plurality of light-emitting devices has a locally thinned portion or the plurality of light-emitting devices each include an island-shaped EL layer. With the structure in which the EL layer has a small thickness portion (also referred to as a thin portion) or the structure in which the EL layer is separated between the light-emitting devices, occurrence of crosstalk between adjacent subpixels can be inhibited. Accordingly, high color reproducibility and high contrast can be achieved in the display device and both high resolution and high display quality of the display device can be achieved. Note that in the display device of one embodiment of the present invention, the EL layer may be formed to have an island shape in some of the subpixels; in this case, the EL layer may be a continuous layer in the other subpixels. In that case, the continuous layer preferably includes a locally thinned portion.

For example, an island-shaped EL layer can be deposited by a vacuum evaporation method using a metal mask. However, this method causes a deviation from the designed shape and position of an island-shaped EL layer due to various influences such as the accuracy of the metal mask, the positional deviation between the metal mask and a substrate, a warp of the metal mask, and an outline expansion of the deposited film due to vapor scattering or the like; accordingly, it is difficult to achieve high resolution and a high aperture ratio of the display device. In addition, the outline of the layer may blur during vapor deposition, whereby the thickness of an end portion may be reduced. That is, the thickness of the island-shaped EL layer formed using a metal mask may vary from area to area. In the case of fabricating a display device with a large size, high definition, or high resolution, the manufacturing yield might be reduced because of low dimensional accuracy of the metal mask and deformation due to heat or the like.

Thus, when the display device of one embodiment of the present invention is fabricated, an island-shaped EL layer is formed without using a shadow mask (e.g., a metal mask).

For example, as the difference between the level of the top surface of an insulating layer that is exposed between adjacent pixel electrodes and the level of the top surface of a pixel electrode (also referred to as a step between adjacent pixel electrodes) is larger, it is easier to form a locally thinned portion in an EL layer and to form an island-shaped EL layer in each light-emitting device by dividing the EL layer. By utilizing a step between adjacent pixel electrodes, the EL layer can be locally thinned or divided in a self-aligned manner in deposition of the EL layer. That is, occurrence of crosstalk can be inhibited without an increase in the number of steps, so that a display device with high color reproducibility and high contrast can be achieved.

Note that when a structure in which the EL layer includes a small thickness portion or a structure in which the EL layer is separated between the light-emitting devices is employed, the light-emitting device might be short-circuited due to contact between an exposed portion if the pixel electrode and the common electrode, for example.

Thus, in the method for fabricating a display device of one embodiment of the present invention, a sidewall insulating layer (also referred to as a sidewall, a sidewall protective layer, an insulating layer, or the like) is provided in contact with a side surface of the pixel electrode. This inhibits the pixel electrode from being in contact with the common electrode, so that preventing a short circuit in the light-emitting device can be prevented and the reliability of the light-emitting device can be increased.

As described above, in the method for fabricating a display device of one embodiment of the present invention, the island-shaped EL layers are formed not by using a fine metal mask but by utilizing a step between the pixel electrodes. Accordingly, a display device with a high resolution or a display device with a high aperture ratio, which has been difficult to achieve, can be achieved.

It is difficult to reduce the distance between adjacent light-emitting devices (also can be referred to as the shortest distance) to less than 10 μm with a formation method using a fine metal mask, for example; however, a method for fabricating a display device according to one embodiment of the present invention can shorten the distance between adjacent light-emitting devices, the distance between adjacent EL layers, the distance between adjacent sidewall insulating layers, or the distance between adjacent pixel electrodes to less than 10 μm, less than or equal to 8 μm, less than or equal to 5 μm, less than or equal to 3 μm, less than or equal to 2 μm, less than or equal to 1.5 μm, less than or equal to 1 μm, or even less than or equal to 0.5 μm, for example, in a process over a glass substrate. Using a light exposure apparatus for LSI can further shorten the distance between adjacent light-emitting devices, adjacent EL layers, or adjacent sidewall insulating layers to less than or equal to 500 nm, less than or equal to 200 nm, less than or equal to 100 nm, or even less than or equal to 50 nm, for example, in a process over a Si wafer. Accordingly, the area of a non-light-emitting region that could exist between two light-emitting devices can be significantly reduced, and the aperture ratio can be close to 100%. For example, in the display device of one embodiment of the present invention, the aperture ratio higher than or equal to 40%, higher than or equal to 50%, higher than or equal to 60%, higher than or equal to 70%, higher than or equal to 80%, or higher than or equal to 90% and lower than 100% can be achieved.

Note that increasing the aperture ratio of the display device can improve the reliability of the display device. Specifically, increasing the aperture ratio can reduce the density of current flowing to the light-emitting device which is needed for obtaining the same display; thus, the lifetime of the display device can be increased.

In addition, the resolution of the display device of one embodiment of the present invention can be higher than or equal to 1000 ppi, preferably higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

In this embodiment, cross-sectional structures of the display device of one embodiment of the present invention are mainly described, and a method for fabricating the display device of one embodiment of the present invention will be described in detail in Embodiment 2.

FIG. 1A is atop view of a display device 100. The display device 100 includes a display portion in which a plurality of pixels 110 are arranged and a connection portion 140 outside the display portion. A plurality of subpixels are arranged in a matrix in the display portion. FIG. 1A shows subpixels in two rows and six columns, which form the pixels 110 in two rows and two columns. The connection portion 140 can also be referred to as a cathode contact portion.

The top surface shape of the subpixels shown in FIG. 1A corresponds to the top surface shape of a light-emitting region. In this specification and the like, a top surface shape refers to a shape in a plan view, i.e., a shape seen from above.

Examples of a top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels shown in FIG. 1A and the circuit components may be placed outside the subpixels. That is, some or all of the transistors included in a subpixel 11R shown in FIG. 1A may be positioned outside the range of the subpixel 11R. The transistor included in the subpixel 11R may be positioned within the range of the subpixel 11R shown in FIG. 1A, may be positioned within the range of a subpixel 11G, may be positioned within the range of a subpixel 11B, or may be provided to extend across two or more of these ranges.

Although the subpixels 11R, 11G, and 11B have the same or substantially the same aperture ratio (also referred to as the same size or the same size of a light-emitting region) in FIG. 1A, one embodiment of the present invention is not limited thereto. Note that the aperture ratio of each of the subpixels 11R, 11G, and 11B can be determined as appropriate. The subpixels 11R, 11G, and 11B may have different aperture ratios, or two or more of the subpixels 11R, 11G, and 11B may have the same or substantially the same aperture ratio.

The pixel 110 shown in FIG. 1A employs stripe arrangement. The pixel 110 shown in FIG. 1A is composed of three subpixels: the subpixel 11R, the subpixel 11G, and the subpixel 11B. The subpixels 11R, 11G, and 11B exhibit light of different colors. The subpixels 11R, 11G, and 11B are subpixels of three colors of red (R), green (G), and blue (B) or subpixels of three colors of yellow (Y), cyan (C), and magenta (M), for example. The number of types of subpixels is not limited to three, and may be four or more. The four subpixels are subpixels of four colors of R, G, B, and white (W), subpixels of four colors of R, G, B, and Y, or subpixels of four types of R, G, B, and infrared light (IR), for example.

In this specification and the like, the row direction is sometimes referred to as X direction and the column direction is sometimes referred to as Y direction. The X direction and the Y direction intersect with each other and are, for example, orthogonal to each other (see FIG. 1A). FIG. 1A shows an example in which subpixels of different colors are arranged in the X direction and subpixels of the same color are arranged in the Y direction.

Although FIG. 1A shows an example where the connection portion 140 is positioned on the lower side of the display portion in the top view, there is no particular limitation on the position of the connection portion 140. The connection portion 140 may be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of connection portions 140 can be one or more.

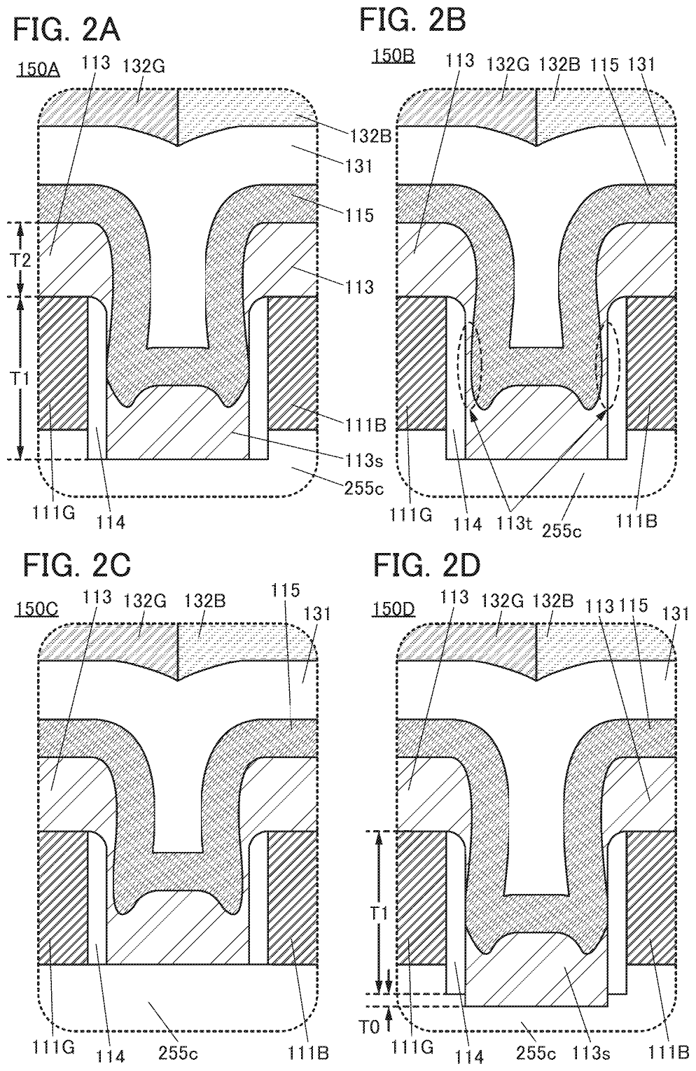

FIG. 1B is a cross-sectional view along dashed-dotted line X1-X2 in FIG. 1A. FIG. 1C is a cross-sectional view along dashed-dotted line Y1-Y2 in FIG. 1A. FIG. 2A is an enlarged view of a region 150A shown in FIG. 1B. FIG. 2B to FIG. 2D show a region 150B to a region 150D that are modification examples of the region 150A.

The subpixel 11R includes a light-emitting device 130R and a coloring layer 132R transmitting red light. Thus, light emitted from the light-emitting device 130R is extracted as red light to the outside of the display device through the coloring layer 132R.

Similarly, the subpixel 11G includes a light-emitting device 130G and a coloring layer 132G transmitting green light. Thus, light emitted from the light-emitting device 130G is extracted as green light to the outside of the display device through the coloring layer 132G.

The subpixel 11B includes a light-emitting device 130B and a coloring layer 132B transmitting blue light. Thus, light emitted from the light-emitting device 130B is extracted as blue light to the outside of the display device through the coloring layer 132B.

Here, an example of blue light is light having a peak wavelength of the emission spectrum of greater than or equal to 400 nm and less than 480 nm. An example of green light is light having a peak wavelength of the emission spectrum of greater than or equal to 480 nm and less than 580 nm. An example of red light is light having a peak wavelength of the emission spectrum of greater than or equal to 580 nm and less than or equal to 700 nm.

A coloring layer is a colored layer that selectively transmits light in a specific wavelength range and absorbs light in the other wavelength ranges. As the coloring layer 132R, a color filter that transmits light in the red wavelength range can be used, for example. As the coloring layer 132G, a color filter that transmits light in the green wavelength range can be used, for example. As the coloring layer 132B, a color filter that transmits light in the blue wavelength range can be used, for example. Examples of materials that can be used for the coloring layer include a metal material, a resin material, and a resin material containing a pigment or dye.

As shown in FIG. 1B, in the display device 100, an insulating layer is provided over a layer 101 including transistors, the light-emitting devices 130R, 130G, and 130B are provided over the insulating layer, and a protective layer 131 is provided to cover these light-emitting devices. The coloring layers 132R, 132G, and 132B are provided over the protective layer 131, and a substrate 120 is bonded onto the coloring layers 132R, 132G, and 132B with a resin layer 122. The coloring layer 132R is provided in a position overlapping with the light-emitting device 130R. The coloring layer 132G is provided in a position overlapping with the light-emitting device 130G. The coloring layer 132B is provided in a position overlapping with the light-emitting device 130B.

The display device of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces. In this embodiment, a top-emission display device is described as an example.

The layer 101 including transistors can employ a stacked-layer structure where a plurality of transistors are provided over a substrate and an insulating layer is provided to cover these transistors, for example. The insulating layer over the transistors may have a single-layer structure or a stacked-layer structure. In FIG. 1B, an insulating layer 255a, an insulating layer 255b over the insulating layer 255a, and an insulating layer 255c over the insulating layer 255b are shown as the insulating layers over the transistors. Note that the insulating layers (the insulating layer 255a to the insulating layer 255c) over the transistors may be regarded as part of the layer 101 including transistors.

As described later, the insulating layer 255c preferably includes a depressed portion between two adjacent light-emitting devices. Thus, when the EL layer is deposited, a large step is provided between adjacent pixel electrodes, so that the EL layer can be easily formed separately for each light-emitting device. FIG. 1B shows an example where a depressed portion is provided in the insulating layer 255c. The insulating layer 255c may have an opening between two adjacent light-emitting devices; in this case, a depressed portion may be provided in the insulating layer 255b.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and a silicon nitride film be used as the insulating layer 255b. The insulating layer 255b preferably has a function of an etching protective film.

Note that in this specification and the like, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

Structure examples of the layer 101 including transistors will be described later in Embodiment 4.

As the light-emitting device, an OLED (Organic Light-Emitting Diode) or a QLED (Quantum-dot Light-Emitting Diode) is preferably used, for example. Examples of a light-emitting substance contained in the light-emitting device include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material). In addition, an LED (Light Emitting Diode) such as a micro LED can also be used as the light-emitting device.

The emission color of the light-emitting device can be infrared, red, green, blue, cyan, magenta, yellow, white, or the like. Furthermore, the color purity can be increased when the light-emitting device has a microcavity structure.

A conductive film that transmits visible light can be used for one of a pair of electrodes included in the light-emitting device through which light is extracted, and a conductive film that reflects visible light can be used for the other of the pair of electrodes of the light-emitting device through which light is not extracted.

One of a pair of electrodes of the light-emitting device functions as an anode and the other electrode functions as a cathode. The case where the pixel electrode functions as an anode and the common electrode functions as a cathode is described below as an example in some cases.

The light-emitting device 130R includes a pixel electrode 111R over the insulating layer 255c, an island-shaped EL layer 113 over the pixel electrode 111R, and a common electrode 115 over the EL layer 113.

The light-emitting device 130G includes a pixel electrode 111G over the insulating layer 255c, the island-shaped EL layer 113 over the pixel electrode 111G, and the common electrode 115 over the EL layer 113.

The light-emitting device 130B includes a pixel electrode 111B over the insulating layer 255c, the island-shaped EL layer 113 over the pixel electrode 111B, and the common electrode 115 over the EL layer 113.

The light-emitting devices 130R, 130G, and 130B each independently include the island-shaped EL layer 113. These EL layers 113 are formed in the same step and have the same structure. Thus, it can be said that these EL layers 113 contain the same light-emitting material.

The EL layer 113 can be configured to emit white light. For example, the EL layer 113 can contain a first light-emitting material that emits blue light and a second light-emitting material that emits light having a longer wavelength than blue light.

Note that in the case where the light-emitting device including the EL layer configured to emit white light has a microcavity structure, light of a specific wavelength such as red, green, or blue is sometimes intensified and emitted.

For example, when the EL layer 113 configured to emit white light has a microcavity structure, red light emission, green light emission, and blue light emission can be obtained from the light-emitting device 130R, the light-emitting device 130G, and the light-emitting device 130B, respectively.

The light-emitting device of this embodiment may have either a single structure (a structure including only one light-emitting unit) or a tandem structure (a structure including a plurality of light-emitting units). The light-emitting unit includes at least one light-emitting layer.

The EL layer 113 includes at least a light-emitting layer. For example, the EL layer 113 can employ a structure including a light-emitting layer that emits blue light and a light-emitting layer that emits light having a longer wavelength than blue light.

In the case where a light-emitting device having a tandem structure is used, for example, the EL layer 113 can employ a structure including a light-emitting unit that emits blue light and a light-emitting unit that emits light with a longer wavelength than blue light. A charge-generation layer is preferably provided between the light-emitting units. With the tandem structure, a light-emitting device capable of high-luminance light emission can be achieved.

In addition, the EL layer 113 may include one or more of a hole-injection layer, a hole-transport layer, a hole-blocking layer, a charge-generation layer, an electron-blocking layer, an electron-transport layer, and an electron-injection layer.

The EL layer 113 may include a hole-injection layer, a hole-transport layer, a light-emitting layer, an electron-transport layer, and an electron-injection layer in this order from the anode side, for example. In addition, an electron-blocking layer may be provided between the hole-transport layer and the light-emitting layer. In addition, a hole-blocking layer may be provided between the electron-transport layer and the light-emitting layer.

In addition, the EL layer 113 may include a first light-emitting unit, a charge-generation layer over the first light-emitting unit, and a second light-emitting unit over the charge-generation layer, for example.

Embodiment 5 can be referred to for more details of the structure and materials of the light-emitting device.

In FIG. 1B, the EL layers 113 included in the light-emitting devices are apart from each other. When the EL layer is provided in an island shape for each light-emitting device, a leakage current between adjacent light-emitting devices can be inhibited. This can prevent unintended light emission due to crosstalk, so that a display device with extremely high contrast can be achieved. Specifically, a display device having high current efficiency at low luminance can be achieved.

A material layer 113s being formed in the same step and having the same structure as the EL layer 113 is positioned over the insulating layer 255c. The material layer 113s is a layer divided from the EL layer 113 in deposition of a layer included in the EL layer 113 and is provided independently over the insulating layer 255c.

Note that a region where the EL layer 113, the common electrode 115, and any of the pixel electrodes 111R, 111G, and 111B overlap with each other can be referred to as a light-emitting region, and is a region where EL light emission can be obtained. The light-emitting region and the region where the material layer 113s is provided are regions where PL (Photoluminescence) emission can be obtained. Thus, the light-emitting region and the region where the material layer 113s is provided can be distinguished from each other by observing EL emission and PL emission.

A sidewall insulating layer 114 is provided to be in contact with a side surface of the pixel electrode 111R, a side surface of the pixel electrode 111G, and a side surface of the pixel electrode 111B. The sidewall insulating layer 114 can inhibit the common electrode 115 from being in contact with any one of the pixel electrodes 111R, 111G, and 111B. Hence, a short circuit of the light-emitting device is inhibited, and the reliability of the light-emitting device can be increased.

As the sidewall insulating layer 114, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

The sidewall insulating layer 114 may have a single-layer structure or a stacked-layer structure.

There is no particular limitation on the method for forming the sidewall insulating layer 114. For the formation of the sidewall insulating layer 114, a sputtering method, a CVD method, a PECVD method, an ALD method, or the like can be used, for example. Specifically, a sputtering method, a CVD method, or a PECVD method which has a higher deposition speed than an ALD method is preferably used because the sidewall insulating layer 114 that is thick enough to ensure the insulating property can be fabricated with high productivity.

For example, as the sidewall insulating layer 114, a silicon oxide film, a silicon nitride film, a silicon oxynitride film, or a silicon nitride oxide film is preferably used. In that case, a highly reliable display device can be fabricated with high productivity.

In addition, as the sidewall insulating layer 114, an aluminum oxide film may be formed by an ALD method. By an ALD method, the sidewall insulating layer 114 can be formed with good coverage.

In FIG. 1B, an insulating layer (also referred to as a bank, a spacer, or the like) covering the end portion of the top surface of the pixel electrode 111R is not provided between the pixel electrode 111R and the EL layer 113. In addition, an insulating layer covering the end portion of the top surface of the pixel electrode 111G is not provided between the pixel electrode 111G and the EL layer 113. Thus, the distance between adjacent light-emitting devices can be extremely short. Accordingly, the display device can have a high resolution or a high definition. In addition, a mask for forming the insulating layer is not needed, which leads to a reduction in manufacturing cost of the display device.

Furthermore, light emitted from the EL layer can be extracted efficiently with a structure where an insulating layer covering part of the top surface (can also be referred to as an end portion of the top surface) of the pixel electrode is not provided between the pixel electrode and the EL layer, i.e., a structure where an insulating layer is not provided between the pixel electrode and the EL layer. Therefore, the viewing angle dependence of the display device of one embodiment of the present invention can be extremely small. A reduction in the viewing angle dependence leads to an increase in visibility of an image on the display device. For example, in the display device of one embodiment of the present invention, the viewing angle (the maximum angle with a certain contrast ratio maintained when the screen is seen from an oblique direction) can be greater than or equal to 1000 and less than 180°, preferably greater than or equal to 1500 and less than or equal to 170°. Note that the above viewing angle refers to that in both the vertical direction and the horizontal direction.

In FIG. 1B, the EL layers 113 are formed to cover the entire top surfaces of the pixel electrodes 111R, 111G, and 111B. With such a structure, the entire top surface of the pixel electrode can be used as a light-emitting region. Furthermore, the aperture ratio can be easily increased as compared with the structure in which the insulating layer covering part of the top surface of the pixel electrode is provided.

The common electrode 115 is shared by the light-emitting devices 130R, 130G, and 130B. The common electrode 115 included in common to the plurality of light-emitting devices is electrically connected to a conductive layer 123 provided in the connection portion 140 (see FIG. 1C). The conductive layer 123 is preferably formed using a conductive layer formed using the same material and the same step as the pixel electrodes 111R, 111G, and 111B.

In FIG. 1C, the conductive layer 123 and the common electrode 115 are directly connected to each other. For example, by using a mask for defining a film formation area (also referred to as an area mask, a rough metal mask, or the like to be distinguished from a fine metal mask), the EL layer 113 and the common electrode 115 can be deposited in different regions.

In the region 150A shown in FIG. 1B and FIG. 2A, the island-shaped EL layer 113 is provided over the pixel electrode 111G, the island-shaped EL layer 113 is provided over the pixel electrode 111B, and the material layer 113s is provided over the insulating layer 255c. The EL layer 113 over the pixel electrode 111G, the EL layer 113 over the pixel electrode 111B, and the material layer 113s are apart from each other.

When the EL layer is separated between light-emitting devices in this manner, occurrence of crosstalk between adjacent subpixels can be inhibited.

Here, the structure of the sidewall insulating layer 114 that is preferable for locally thinning of the EL layer 113 and dividing the EL layer 113 in a self-aligned manner in deposition of the EL layer 113 will be described.

A height T1 of the sidewall insulating layer 114 shown in FIG. 2A is preferably greater than or equal to 0.5 times, further preferably greater than or equal to 0.8 times, still further preferably greater than or equal to 1 time, and yet still further preferably greater than or equal to 1.5 times the thickness of the EL layer 113.

The thickness of the sidewall insulating layer 114 in a direction perpendicular to the substrate surface is preferably used as the height T1 of the sidewall insulating layer 114. Note that in FIG. 2A, the height T1 of the sidewall insulating layer 114 can be regarded as the sum of the thickness of the pixel electrode and the depth of the depressed portion provided in the insulating layer 255c.

As shown in FIG. 2A, a thickness T2 of the EL layer 113 in a region overlapping with the top surface of the pixel electrode is preferably used as the thickness of the EL layer 113.

In addition, when the height T1 of the sidewall insulating layer 114 is too high, the common electrode 115 might also be locally thinned or divided. Therefore, the height T1 of the sidewall insulating layer 114 is preferably less than or equal to 3 times, further preferably less than or equal to 2 times the thickness of the EL layer 113.

As described in Embodiment 2 later, the distance between the deposition source and the substrate is preferably small when the common electrode 115 is formed. This can improve the coverage of the formation surface with the common electrode 115.

As described above, it is possible to prevent formation of a divided portion and a locally thinned portion in the common electrode 115. This can inhibit a connection defect due to the disconnected portion and an increase in electric resistance due to the locally thinned portion in the common electrode 115 between the light-emitting devices. Accordingly, the display quality of the display device of one embodiment of the present invention can be improved.

An angle formed between at least part of a surface of the sidewall insulating layer 114 which is in contact with the EL layer 113 (e.g., a side surface) and the substrate surface is preferably perpendicular or substantially perpendicular. The angle can also be referred to as an angle formed between part of a surface of the sidewall insulating layer 114 which is in contact with the EL layer 113 (e.g., a side surface) and the bottom surface. The angle is preferably greater than or equal to 60°, further preferably greater than or equal to 80°, still further preferably greater than or equal to 85°, and preferably less than or equal to 140°, further preferably less than or equal to 110°, still further preferably less than or equal to 100°, yet still further preferably less than or equal to 95°.

In order to make the angle within the above-described numerical range, the angle formed between a side surface of the pixel electrode and the substrate surface is preferably a right angle or a substantially right angle. The angle formed by the side surface of the pixel electrode and the substrate surface is preferably greater than or equal to 60°, further preferably greater than or equal to 80°, still further preferably greater than or equal to 85°, and preferably less than or equal to 140°, further preferably less than or equal to 110°, still further preferably less than or equal to 100°, yet still further preferably less than or equal to 95°.

The region 150B shown in FIG. 2B and the region 150C shown in FIG. 2C are examples in which the EL layer 113 is provided to cover the pixel electrode 111G, the sidewall insulating layer 114, the insulating layer 255c, and the pixel electrode 111B.

A region 113t shown in FIG. 2B is a portion which has a smaller thickness than other portions in the EL layer 113.

Note that the thickness of the region 113t refers not to the thickness in a direction perpendicular to a reference surface such as a substrate surface but to the thickness in the normal direction of a formation surface. Thus, in the case where the formation surface has unevenness, the direction for specifying the thickness is different depending on a place. For example, the thickness of the EL layer 113 in the region 113t can be regarded as the thickness in the normal direction of the side surface of the sidewall insulating layer 114.

As described above, even with the structure where the EL layer 113 is locally thinned, occurrence of crosstalk between adjacent subpixels can be inhibited.

The structure of the region 150C shown in FIG. 2C is different from that of the region 150B in that the insulating layer 255c does not include a depressed portion between two adjacent light-emitting devices.

The region 150D shown in FIG. 2D is an example in which the insulating layer 255c includes two depressed portions, a shallow depressed portion and a deep depressed portion, between two adjacent light-emitting devices.

A depressed portion may be formed in the insulating layer 255c in the processing of a conductive film to be the pixel electrode. Furthermore, a depressed portion may be formed in the insulating layer 255c in the processing of an insulating film to be the sidewall insulating layer 114. Thus, a shallow depressed portion and a deep depressed portion are provided. In FIG. 2D, the sidewall insulating layer 114 is over and in contact with the shallow depressed portion, and the material layer 113s is over and in contact with the deep depressed portion.

Note that a distance T0 between the surface of the deep depressed portion of the insulating layer 255c and the bottom surface of the sidewall insulating layer 114 shown in FIG. 2D is also a parameter that affects local thinning of the EL layer 113 or division of the EL layer 113.

For the same reason as the above, the sum of the distance T0 and the height T1 of the sidewall insulating layer 114 is preferably greater than or equal to 0.5 times, further preferably greater than or equal to 0.8 times, still further preferably greater than or equal to 1 time, and yet still further preferably greater than or equal to 1.5 times the thickness of the EL layer 113, for example. In addition, the sum of the distance T0 and the height T1 of the sidewall insulating layer 114 is preferably less than or equal to 3 times, further preferably less than or equal to 2 times the thickness of the EL layer 113.

Note that in FIG. 2D, the sum of the distance T0 and the height T1 of the sidewall insulating layer 114 can also be referred to as the sum of the thickness of the pixel electrode and the depth of the depressed portion provided in the insulating layer 255c.

As described above, in the display device of one embodiment of the present invention, providing the sidewall insulating layer 114 in contact with the side surface can inhibit the pixel electrode from being in contact with the common electrode 115, so that a short circuit in the light-emitting device can be prevented. Furthermore, when the height and the shape of the sidewall insulating layer 114 are preferable for local thinning of the EL layer 113 or division of the EL layer 113, occurrence of crosstalk between adjacent subpixels can be inhibited. Furthermore, when the height of the sidewall insulating layer 114 are preferable for inhibiting division and thinning the common electrode 115, a connection defeat between light-emitting devices and an increase in electric resistance can be inhibited.

It can also be said that the display device of one embodiment of the present invention is configured to intentionally generate disconnection in the EL layer 113 and to prevent disconnection in the common electrode 115.

The protective layer 131 is preferably provided over the light-emitting devices 130R, 130G, and 130B. Providing the protective layer 131 can improve the reliability of the light-emitting devices. The protective layer 131 may have a single-layer structure or a stacked-layer structure of two or more layers.

There is no limitation on the conductivity of the protective layer 131. As the protective layer 131, at least one of an insulating film, a semiconductor film, and a conductive film can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display device can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the sidewall insulating layer 114. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

The protective layer 131 may have a stacked-layer structure of two layers which are formed by different film formation methods. Specifically, the first layer of the protective layer 131 may be formed by an ALD method, and the second layer of the protective layer 131 may be formed by a sputtering method.

Furthermore, the protective layer 131 may include an organic film. For example, the protective layer 131 may include both an organic film and an inorganic film.

Examples of the organic material which can be used for the protective layer 131 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. Alternatively, for the protective layer 131, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

As shown in FIG. 1B and the like, in the case where the coloring layers 132R, 132G, and 132B and the like are directly formed over the protective layer 131, it is preferable to use a layer having a planarization function as the protective layer 131. An organic film is preferably used as the protective layer 131 because the planarity of the surface of the protective layer 131 can be improved.

A light-blocking layer may be provided on the surface of the substrate 120 on the resin layer 122 side. Moreover, a variety of optical members can be provided outside the substrate 120 (the surface opposite to the resin layer 122 side). Examples of optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, it is preferable to provide, as the surface protective layer, a glass layer or a silica layer (SiOₓ layer) because the surface contamination and generation of damage can be inhibited. For the surface protective layer, DLC (diamond like carbon), aluminum oxide (AlOₓ), a polyester-based material, a polycarbonate-based material, or the like may be used. For the surface protective layer, a material having high visible-light transmittance is preferably used. The surface protective layer is preferably formed using a material with high hardness.

For the substrate 120, glass, quartz, ceramic, sapphire, a resin, a metal, an alloy, a semiconductor, or the like can be used. For the substrate through which light from the light-emitting device is extracted, a material that transmits the light is used. When a flexible material is used for the substrate 120, the display device can have increased flexibility. Furthermore, a polarizing plate may be used as the substrate 120.

For the substrate 120, it is possible to use polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, and the like. Glass that is thin enough to have flexibility may be used as the substrate 120.

In the case where a circularly polarizing plate overlaps with the display device, a highly optically isotropic substrate is preferably used as the substrate included in the display device. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, any of a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet or the like may be used.

As materials that can be used for a gate, a source, and a drain of a transistor and conductive layers such as wirings and electrodes included in the display device, any of metals such as aluminum, titanium, chromium, nickel, copper, yttrium, zirconium, molybdenum, silver, tantalum, and tungsten, or an alloy containing any of these metals as its main component can be given, for example. A single layer or a stacked-layer structure including a film containing any of these materials can be used.

For a conductive material having a light-transmitting property, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), it is preferably thinned so as to have a light-transmitting property. Furthermore, a stacked-layer film of the above materials can be used for a conductive layer. For example, a stacked film of indium tin oxide and an alloy of silver and magnesium, or the like is preferably used to increase the conductivity. They can also be used for conductive layers such as wirings and electrodes included in the display device, and conductive layers (e.g., a conductive layer functioning as a pixel electrode or a counter electrode) included in a light-emitting device.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

Note that the pixel electrodes 111R, 111G, and 111B may have different thicknesses. Alternatively, optical adjustment layers with different thicknesses may be provided over the pixel electrodes 111R, 111G, and 111B.

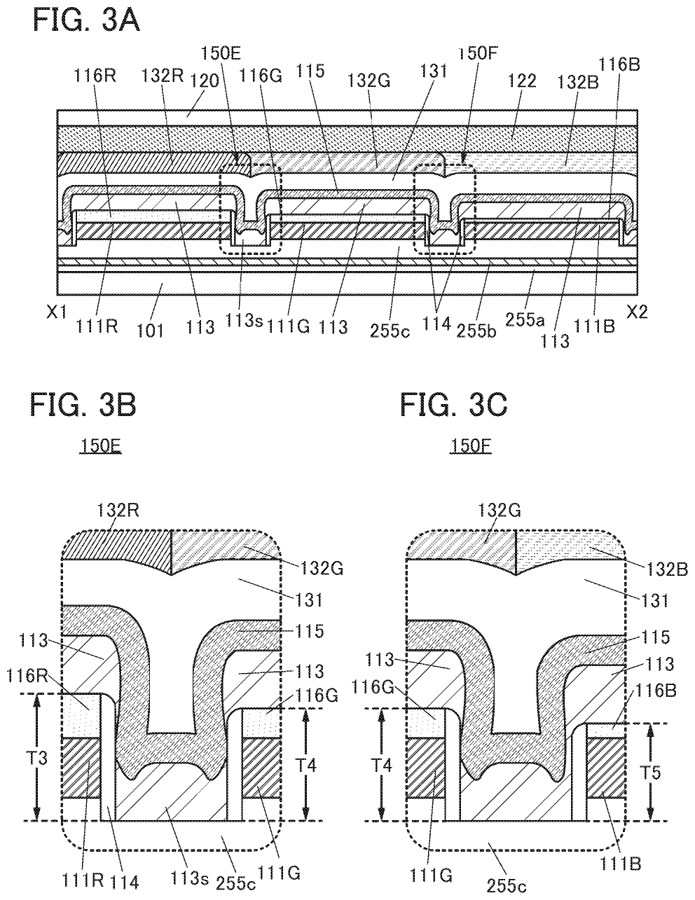

FIG. 3A shows a modification example of FIG. 1B. FIG. 3B and FIG. 3C are enlarged views of a region 150E and a region 150F shown in FIG. 3A.

In FIG. 3A, an optical adjustment layer 116R is provided over the pixel electrode 111R, an optical adjustment layer 116G is provided over the pixel electrode 111G, and an optical adjustment layer 116B is provided over the pixel electrode 111B.

FIG. 3A shows an example in which the thickness of the optical adjustment layer 116R is larger than that of the optical adjustment layer 116G and the thickness of the optical adjustment layer 116G is larger than that of the optical adjustment layer 116B. The thickness of each optical adjustment layer is preferably determined in the following manner: the thickness of the optical adjustment layer 116R is set to intensify red light, the thickness of the optical adjustment layer 116G is set to intensify green light, and the thickness of the optical adjustment layer 116B is set to intensify blue light. This achieves a microcavity structure, so that the color purity of light emitted from each light-emitting device can be increased.

The optical adjustment layer is preferably formed using a conductive material transmitting visible light among the conductive materials that can be used for the electrode of the light-emitting device.

In the region 150E shown in FIG. 3A and FIG. 3B, the island-shaped EL layer 113 is provided over the pixel electrode 111R, the island-shaped EL layer 113 is provided over the pixel electrode 111G, and the material layer 113s is provided over the insulating layer 255c. The EL layer 113 over the pixel electrode 111R, the EL layer 113 over the pixel electrode 111G, and the material layer 113s are apart from each other.

In the region 150F shown in FIG. 3A and FIG. 3C, the island-shaped EL layer 113 is provided over the pixel electrode 111G and the island-shaped EL layer 113 is provided to cover the insulating layer 255c, the sidewall insulating layer 114, and the pixel electrode 111B. The EL layer 113 over the pixel electrode 111G and the EL layer 113 covering the insulating layer 255c, the sidewall insulating layer 114, and the pixel electrode 111B are apart from each other.

When the thickness of the optical adjustment layer is different between subpixels, the height of the sidewall insulating layer 114 is also different between the subpixels in some cases. In FIG. 3B and FIG. 3C, the height T3 of the sidewall insulating layer 114 covering the side surface of the pixel electrode 111R is higher than the height T4 of the sidewall insulating layer 114 covering the side surface of the pixel electrode 111G and the height T5 of the sidewall insulating layer 114 covering the side surface of the pixel electrode 111B, and the height T4 of the sidewall insulating layer 114 covering the side surface of the pixel electrode 111G is higher than the height T5 of the sidewall insulating layer 114 covering the side surface of the pixel electrode 111B.

As shown in FIG. 3C, depending on the value of the height T5, the EL layer 113 is not divided by the sidewall insulating layer 114 covering the side surface of the pixel electrode 111B, and one island-shaped the EL layer 113 may include a portion positioned over the insulating layer 255c, a portion covering the sidewall insulating layer 114, and a portion covering the top surface of the pixel electrode 111B. However, in FIG. 3C, the EL layer 113 is divided by the sidewall insulating layer 114 covering the side surface of the pixel electrode 111G. That is, island-shaped EL layers are independently provided for adjacent light-emitting devices; thus, occurrence of crosstalk between adjacent subpixels can be inhibited.

Note that depending on the value of the height T4, the EL layer 113 is not divided by the sidewall insulating layer 114 covering the side surface of the pixel electrode 111G in some cases. That is, one island-shaped EL layer 113 may cover top surfaces of the insulating layer 255c, the sidewall insulating layer 114, the pixel electrode 111G, and the pixel electrode 111B. Also in this case, a portion covering the sidewall insulating layer 114 is thinner than the other portions; thus, occurrence of crosstalk between adjacent subpixels can be inhibited.

As described above, one embodiment of the present invention also includes a structure in which the EL layer 113 is formed in an island shape in some light-emitting devices, and the EL layer 113 is formed as a continuous layer in the other light-emitting devices. For example, the display device of one embodiment of the present invention may include both the region 150A shown in FIG. 2A and the region 150B shown in FIG. 2B.

FIG. 1B and FIG. 3A each show an example in which the coloring layers 132R, 132G, and 132B are directly provided over the light-emitting device with the protective layer 131 therebetween. With such a structure, the alignment accuracy of the light-emitting devices and the coloring layers can be improved. Such a structure is preferably employed, in which case the distance between the light-emitting devices and the coloring layers can be reduced and thus, color mixing can be inhibited and the viewing angle characteristics can be improved.

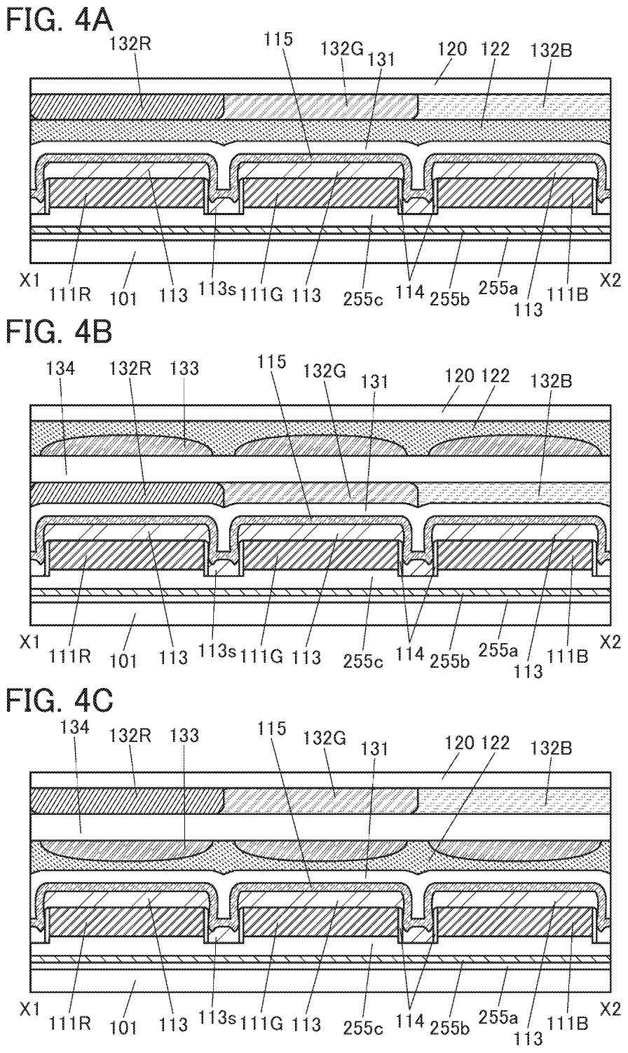

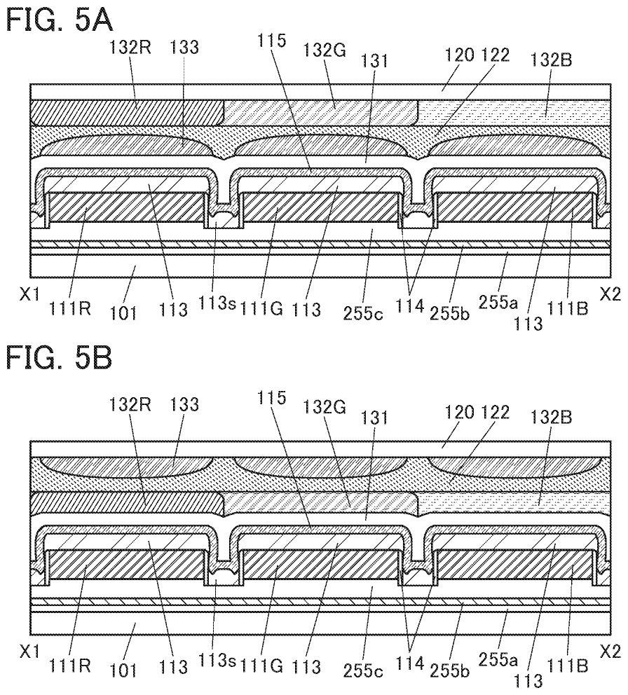

FIG. 4A to FIG. 4C and FIG. 5A and FIG. 5B show cross-sectional views along the dashed-dotted line X1-X2 in FIG. 1A.

Alternatively, as shown in FIG. 4A, the substrate 120 provided with the coloring layers 132R, 132G, and 132B may be attached to the protective layer 131 with the resin layer 122. The coloring layers 132R, 132G, and 132B are provided on the substrate 120, whereby the heat treatment temperature in the forming process of the coloring layers 132R, 132G, and 132B can be increased.

As shown in FIG. 4B and FIG. 4C, a lens array 133 may be provided in the display device. The lens array 133 can be provided to overlap with a light-emitting device.

FIG. 4B shows an example in which the coloring layers 132R, 132G, and 132B are provided over the light-emitting devices with the protective layer 131 therebetween, an insulating layer 134 is provided over the coloring layers 132R, 132G, and 132B, and the lens array 133 is provided over the insulating layer 134. The coloring layer 132R, the coloring layer 132G, the coloring layer 132B, and the lens array 133 are directly formed over the substrate provided with the light-emitting devices, whereby the alignment accuracy of the light-emitting devices and the coloring layers or the lens array can be improved.

For the insulating layer 134, one or both of an inorganic insulating film and an organic insulating film can be used. The insulating layer 134 may have either a single-layer structure or a stacked-layer structure. For the insulating layer 134, a material that can be used for the protective layer 131 can be used, for example. The insulating layer 134 preferably has a planarization function. Light emitted by the light-emitting device is extracted through the insulating layer 134, so that the insulating layer 134 preferably has a high visible-light-transmitting property.

In FIG. 4B, light emitted by the light-emitting device passes through the coloring layer and then passes through the lens array 133, resulting in being extracted to the outside of the display device. The distance between the light-emitting device and the coloring layers is reduced, so that color mixture can be inhibited and the viewing angle characteristics can be improved, which is preferable. Note that the lens array 133 may be provided over the light-emitting device and the coloring layer may be provided over the lens array 133.

FIG. 4C shows an example in which the substrate 120 provided with the coloring layers 132R, 132G, 132B, and the lens array 133 is bonded onto the protective layer 131 with the resin layer 122. The substrate 120 is provided with the coloring layers 132R, 132G, 132B, and the lens array 133, whereby the heat treatment temperature in the forming process of them can be increased.

In the example shown in FIG. 4C, the coloring layers 132R, 132G, and 132B are provided in contact with the substrate 120, the insulating layer 134 is provided in contact with the coloring layers 132R, 132G, and 132B, and the lens array 133 is provided in contact with the insulating layer 134.

In FIG. 4C, light emitted by the light-emitting device passes through the lens array 133 and then passes through the coloring layer, resulting in being extracted to the outside of the display device. Note that the lens array 133 may be provided in contact with the substrate 120, the insulating layer 134 may be provided in contact with the lens array 133, and the coloring layer may be provided in contact with the insulating layer 134. In this case, light emitted by the light-emitting device passes through the coloring layer and then passes through the lens array 133, resulting in being extracted to the outside of the display device.

As shown in FIG. 5A and FIG. 5B, either the lens array or the coloring layers may be provided on the protective layer 131 and the other may be provided on the substrate 120.

FIG. 5A is an example in which the lens array 133 is provided over the light-emitting devices with the protective layer 131 therebetween, and the substrate 120 provided with the coloring layers 132R, 132G, and 132B is bonded onto the lens array 133 and the protective layer 131 with the resin layer 122.

FIG. 5B shows an example in which the coloring layers 132R, 132G, and 132B are provided over the light-emitting devices with the protective layer 131 therebetween, and the substrate 120 provided with the lens array 133 is bonded onto the coloring layers 132R, 132G, and 132B with the resin layer 122.

The lens array 133 may include a convex surface facing the substrate 120 side or a convex surface facing the light-emitting device side.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used, for example. The lens array 133 may be directly formed over the substrate or the light-emitting device; alternatively, a lens array separately formed may be bonded thereto.

It is preferable that coloring layers of different colors include a region where they overlap with each other. The region where the coloring layers of different colors overlap with each other can function as a light-blocking layer. Thus, reflection of external light can be further reduced.

In the display device of one embodiment of the present invention, generation of leakage current between subpixels can be inhibited because the EL layer is locally thinned or an island-shaped EL layer is provided in each light-emitting device. This can prevent unintended light emission due to crosstalk, so that a display device with extremely high contrast can be achieved.

In the display device of one embodiment of the present invention, a sidewall insulating layer is provided on a side surface of the pixel electrode. This can inhibit a short circuit in the light-emitting device and accordingly a highly reliable display device can be achieved.

This embodiment can be combined with any of the other embodiments as appropriate. In this specification, in the case where a plurality of structure examples are described in one embodiment, the structure examples can be combined as appropriate.

### Embodiment 2

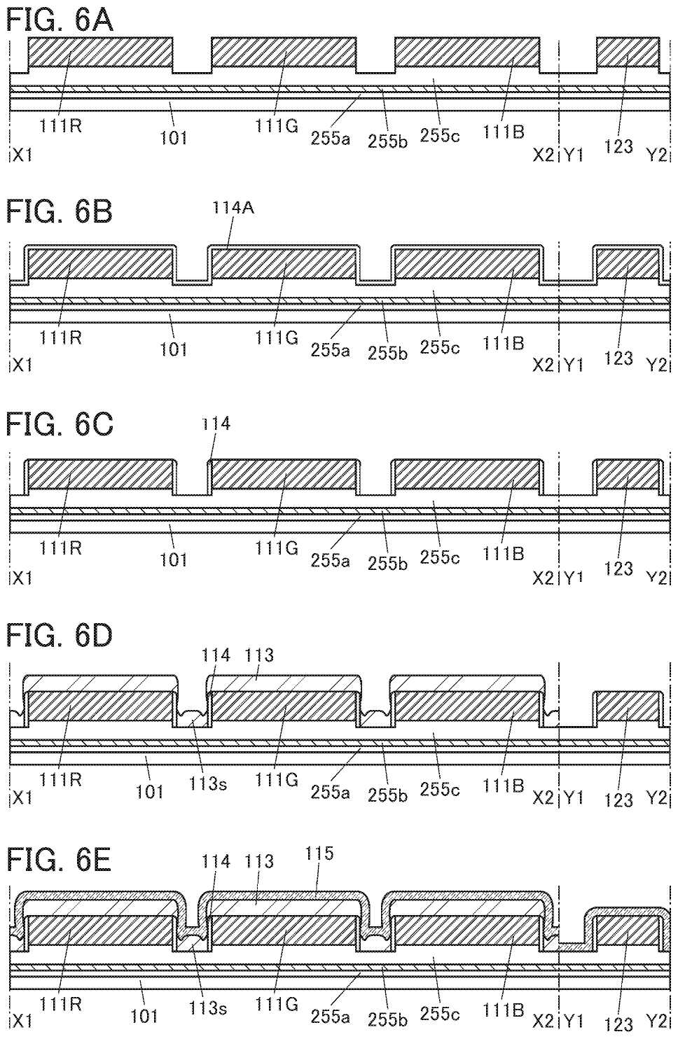

In this embodiment, a display device of one embodiment of the present invention and a fabricating method thereof will be described with reference to FIG. 6. Note that as for a material and a formation method of each component, portions similar to the portions described in Embodiment 1 are not described in some cases. Details of a structure of a light-emitting device will be described in Embodiment 5.

FIG. 6 shows a cross-sectional view along the dashed-dotted line X1-X2 and a cross-sectional view along the dashed-dotted line Y1-Y2 in FIG. 1A side by side.

Thin films included in the display device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic chemical vapor deposition (MOCVD) method.

Alternatively, thin films included in the display device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

Thin films included in the display device can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

As light used for light exposure in a photolithography method, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Light exposure may be performed by liquid immersion exposure technique. As the light used for light exposure, extreme ultraviolet (EUV) light or X-rays may also be used. Instead of the light used for the light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblasting method, or the like can be used.

First, the insulating layer 255a, the insulating layer 255b, and the insulating layer 255c are formed in this order over the layer 101 including transistors. Next, the conductive layer 123 and the pixel electrodes 111R, 111G, and 111B are formed over the insulating layer 255c (FIG. 6A).

First, a conductive film to be a pixel electrode is formed, a resist mask is formed by a photolithography method, and an unnecessary portion of the conductive film is removed by etching. After that, the resist mask is removed to form the pixel electrode 111R, the pixel electrode 111G, and the pixel electrode 111B. The conductive film to be the pixel electrode can be formed by a sputtering method or a vacuum evaporation method, for example. The conductive film can be processed by a wet etching method or a dry etching method. The conductive film is preferably processed by anisotropic etching.

In processing of the conductive film, it is preferable to form a depressed portion in the insulating layer 255c by processing the insulating layer 255c. This can increase the height of the sidewall insulating layer 114 to be formed later. Accordingly, local thinning of the EL layer 113 to be formed later or division of the EL layer 113 for each light-emitting device can be facilitated. Note that other examples of the structure of one embodiment of the present invention include a structure in which an opening is provided in the insulating layer 255c and a depressed portion is provided in the insulating layer 255b, and a structure in which an opening is provided in the insulating layers 255b and 255c and a depressed portion is provided in the insulating layer 255a. In the case where the pixel electrode is thick enough, for example, the depressed portion and the opening are not necessarily provided in the insulating layer 255c.

In other words, the thickness of the insulating layer 255c in a region overlapping with none of the pixel electrodes 111R, 111G, and 111B and the conductive layer 123 is preferably smaller than the thickness of the insulating layer 255c in a region overlapping with the pixel electrodes 111R, 111G, and 111B or the conductive layer 123.

Next, an insulating film 114A is formed over the insulating layer 255c, the pixel electrodes 111R, 111G, and 111B, and the conductive layer 123 (FIG. 6B).

The insulating film 114A is a layer to be the sidewall insulating layer 114 by processing later. Thus, the insulating film 114A can employ the structure that is described in Embodiment 1 and can be used for the sidewall insulating layer 114.

Next, the sidewall insulating layer 114 is formed by processing the insulating film 114A (FIG. 6C). By processing the insulating film 114A, the top surfaces of the insulating layer 255c, the pixel electrodes 111R, 111G, and 111B, and the conductive layer 123 are exposed. The sidewall insulating layer 114 is provided in contact with side surfaces of the pixel electrodes 111R, 111G, and 111B and the conductive layer 123.

The sidewall insulating layer 114 can be formed by performing etching substantially uniformly on the top surface of the insulating film 114A, for example. Such uniform etching for planarization is also referred to as etch-back processing. Note that the sidewall insulating layer 114 can also be formed by a photolithography method.

The insulating film 114A can be processed by a wet etching method or a dry etching method and is preferably processed by a dry etching method. The insulating film 114A is preferably processed by anisotropic etching.

Note that in processing of the insulating film 114A, the insulating layer 255c may also be processed to form a depressed portion in the insulating layer 255c. The depressed portion formed in the insulating layer 255c facilitates local thinning of the EL layer 113 to be formed later or division of the EL layer 113 for each light-emitting device. Note that other examples of the structure of one embodiment of the present invention include a structure in which an opening is provided in the insulating layer 255c and a depressed portion is provided in the insulating layer 255b, and a structure in which an opening is provided in the insulating layers 255b and 255c and a depressed portion is provided in the insulating layer 255a. In the case where the pixel electrode is thick enough, for example, the depressed portion and the opening are not necessarily provided in the insulating layer 255c.

In other words, in FIG. 6C, the thickness of the insulating layer 255c in a region exposed (a region overlapping with none of the sidewall insulating layer 114, the pixel electrodes 111R, 111G, and 111B, and the conductive layer 123) may be smaller than the thickness of the insulating layer 255c in a region overlapping with the sidewall insulating layer 114.

An end portion of the sidewall insulating layer 114 can have a rounded shape. For example, the end portion of the sidewall insulating layer 114 is rounded as shown in FIG. 6C, FIG. 1i, FIG. 2A to FIG. 2D, and the like when an upper portion of the insulating film 114A is etched by anisotropic etching in formation of the sidewall insulating layer 114 by a dry etching method. The rounded shape of the end portion of the sidewall insulating layer 114 is preferable because the coverage with a film to be formed later can be improved.

Next, the EL layer 113 is formed over the pixel electrodes 111R, 111G, and 111B (FIG. 6D). The EL layer 113 contains a light-emitting material that emits blue light and a light-emitting material that emits light having a longer wavelength than blue light. FIG. 6D shows an example in which the island-shaped EL layer 113 is provided for each light-emitting device. That is, the island-shaped EL layer 113 is provided over each of the pixel electrodes 111R, 111G, and 111B.

In a region between the pixel electrode 111R and the pixel electrode 111G, the material layer 113s is provided over the insulating layer 255c. Similarly, the material layer 113s is provided over the insulating layer 255c in a region between the pixel electrode 111G and the pixel electrode 111B and a region between the pixel electrode 111B and the pixel electrode 111R. The material layer 113s is formed in the same step and has the same structure as the EL layer 113.

As shown in FIG. 6D, the EL layer 113 is not formed over the conductive layer 123 in the cross-sectional view along the dashed-dotted line Y1-Y2. The EL layer 113 can be formed only in an intended region by using an area mask, for example.

The EL layer 113 can be formed by an evaporation method, specifically a vacuum evaporation method, for example. The EL layer 113 may be formed by a transfer method, a printing method, an inkjet method, a coating method, or the like.

Next, the common electrode 115 is formed over the EL layer 113 and the conductive layer 123 (FIG. 6E).

The common electrode 115 can be formed by a sputtering method or a vacuum evaporation method, for example. Alternatively, a film formed by an evaporation method and a film formed by a sputtering method may be stacked.

In the formation of the common electrode 115, the distance between the deposition source and the substrate is preferably small. For example, the distance between the deposition source and the substrate in the formation of the common electrode 115 is preferably smaller than that in the formation of the EL layer 113. Thus, it is possible to improve the coverage of the formation surface with the common electrode 115, and to prevent formation of a locally thinned portion in the common electrode 115. Accordingly, in the common electrode 115, a connection defect due to the disconnected portion and an increase in electric resistance due to the locally thinned portion can be inhibited.

After that, the protective layer 131 is formed over the common electrode 115. In the case of employing the structure including the coloring layers over the protective layer 131 as shown in FIG. 1B and the like, the coloring layers 132R, 132G, and 132B are provided over the protective layer 131 after the above step. Then, the substrate 120 is bonded onto the coloring layers 132R, 132G, and 132B with the resin layer 122, whereby the display device can be fabricated (FIG. 1). In addition, in the case of employing the structure including the coloring layers on the substrate 120 side as shown in FIG. 4A and the like, the coloring layers 132R, 132G, and 132B are provided over the substrate 120 in advance and then the substrate 120 is bonded, whereby the display device can be fabricated.

Examples of methods for forming the protective layer 131 include a vacuum evaporation method, a sputtering method, a CVD method, and an ALD method.

As described above, in the fabricating method of a display device of this embodiment, the island-shaped EL layer 113 is formed not by using a fine metal mask; thus, the island-shaped EL layer 113 can be formed to have a uniform thickness. Consequently, a high-resolution display device or a display device with a high aperture ratio can be obtained. Furthermore, even when the resolution or the aperture ratio is high and the distance between subpixels is extremely short, contact between the EL layers 113 can be inhibited in adjacent subpixels. As a result, generation of a leakage current between the subpixels can be inhibited. This can prevent unintended light emission due to crosstalk, so that a display device with extremely high contrast can be achieved.

Furthermore, in the method for fabricating a display device of this embodiment, subpixels of three colors can be separately formed just by forming one kind of EL layer. This can reduce the number of fabrication steps, leading to fabrication of a display device with a high yield.

This embodiment can be combined with any of the other embodiments as appropriate.

### Embodiment 3

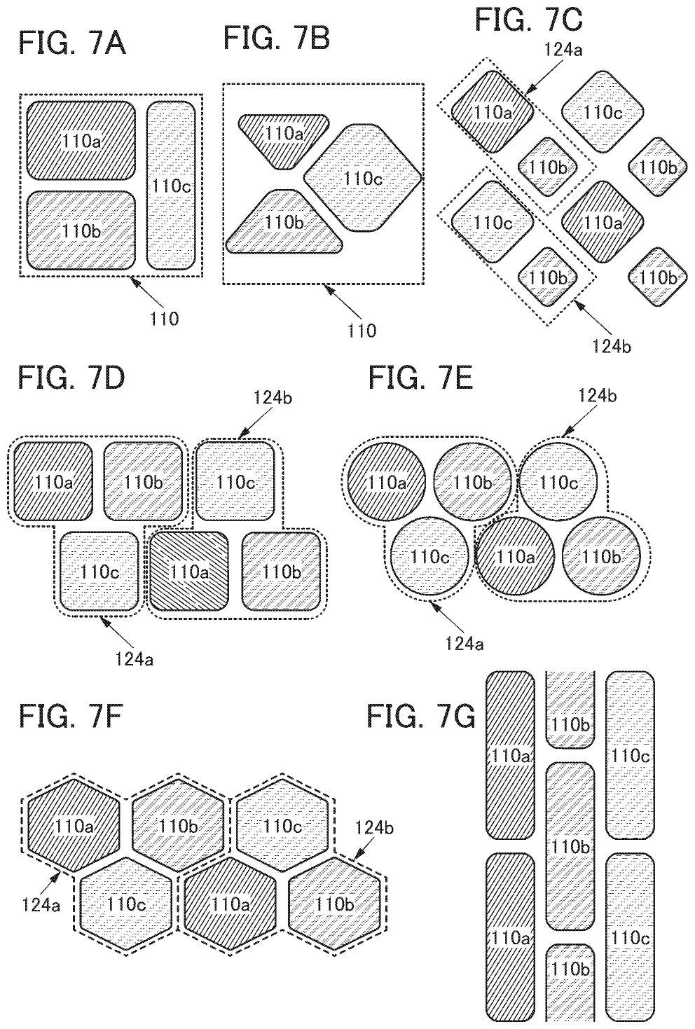

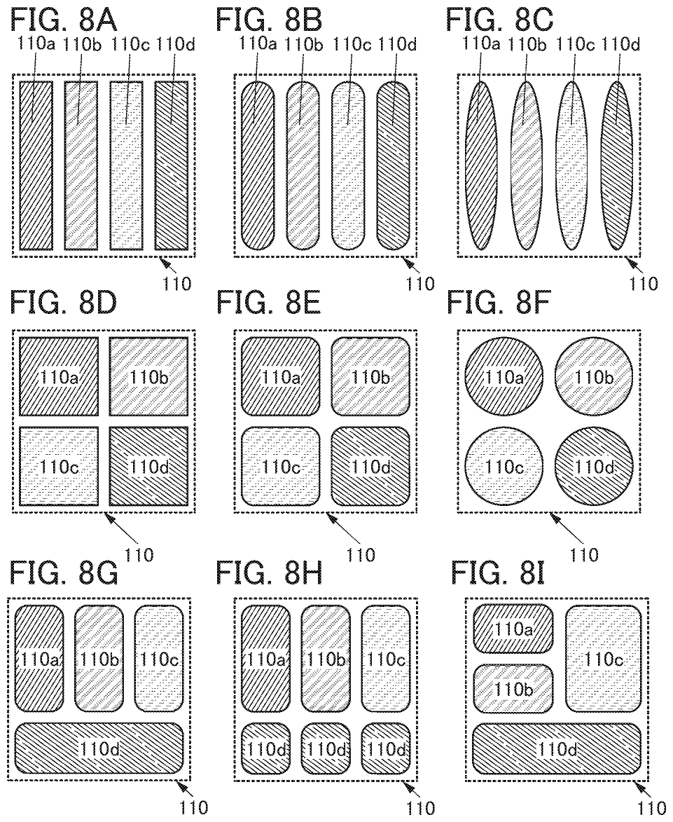

In this embodiment, a display device of one embodiment of the present invention will be described with reference to FIG. 7 and FIG. 8.

### [Pixel Layout]

In this embodiment, pixel layouts different from the layout in FIG. 1A will be mainly described. There is no particular limitation on the arrangement of subpixels, and a variety of methods can be employed. The arrangement of subpixels may be stripe arrangement, S stripe arrangement, matrix arrangement, delta arrangement, Bayer arrangement, or PenTile arrangement, for example.

The top surface shape of the subpixel shown in a diagram in this embodiment corresponds to the top surface shape of a light-emitting region.

Examples of a top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels shown in a diagram and the circuit components may be placed outside the subpixels. The arrangement of the circuits and the arrangement of the light-emitting devices are not necessarily the same, and different arrangement methods may be employed. For example, the arrangement of the circuits may be stripe arrangement, and the arrangement of the light-emitting devices may be S-stripe arrangement.

The pixel 110 shown in FIG. 7A employs S-stripe arrangement. The pixel 110 shown in FIG. 7A consists of three subpixels 110a, 110b, and 110c.

The pixel 110 shown in FIG. 7B includes the subpixel 110a whose top surface has a rough triangle or rough trapezoidal shape with rounded corners, the subpixel 110b whose top surface has a rough triangle or rough trapezoidal shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

Pixels 124a and 124b shown in FIG. 7C employ PenTile arrangement. FIG. 7C shows an example in which the pixels 124a, each of which includes the subpixel 110a and the subpixel 110b, and the pixels 124b, each of which includes the subpixel 110b and the subpixel 110c, are alternately arranged.

The pixels 124a and 124b shown in FIG. 7D to FIG. 7F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 7D is an example where the top surface of each subpixel has a rough tetragonal shape with rounded corners, FIG. 7E is an example where the top surface of each subpixel is circular, and FIG. 7F is an example where the top surface of each subpixel has a rough hexagonal shape with rounded corners.

In FIG. 7F, subpixels are placed inside respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110a, the subpixel 110a is surrounded by three subpixels 110b and three subpixels 110c that are alternately arranged.

FIG. 7G shows an example where subpixels of different colors are arranged in a zigzag manner. Specifically, the positions of the top sides of two subpixels arranged in the column direction (e.g., the subpixel 110a and the subpixel 110b, or the subpixel 110b and the subpixel 110c) are not aligned in the top view.

For example, in each pixel shown in FIG. 7A to FIG. 7G, it is preferable that the subpixel 110a be a subpixel R that emits red light, the subpixel 110b be a subpixel G that emits green light, and the subpixel 110c be a subpixel B that emits blue light. Note that the structure of the subpixels is not limited to this, and the colors and arrangement order of the subpixels can be determined as appropriate. For example, the subpixel 110b may be the subpixel R that emits red light and the subpixel 110a may be the subpixel G that emits green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a pixel electrode can have a polygonal shape with rounded corners, an elliptical shape, a circular shape, or the like. In the display device of one embodiment of the present invention, the top surface shape of the EL layer and the top surface shape of the light-emitting device may each be a polygonal shape with rounded corners, an elliptical shape, a circular shape, or the like due to the influence of the top surface shape of the pixel electrode.

Note that to obtain a desired top surface shape of the pixel electrode, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As shown in FIG. 8A to FIG. 8I, the pixel can include four types of subpixels.

The pixels 110 shown in FIG. 8A to FIG. 8C each employ stripe arrangement.

FIG. 8A is an example in which each subpixel has a rectangular top surface shape, FIG. 8B is an example in which each subpixel has a top surface shape formed by combining two half circles and a rectangle, and FIG. 8C is an example in which each subpixel has an elliptical top surface shape.

The pixels 110 shown in FIG. 8D to FIG. 8F each employ matrix arrangement.

FIG. 8D is an example in which each subpixel has a square top surface shape, FIG. 8E is an example in which each subpixel has a substantially square top surface shape with rounded corners, and FIG. 8F is an example in which each subpixel has a circular top surface shape.

FIG. 8G and FIG. 8H each show an example in which one pixel 110 is composed of two rows and three columns.

The pixel 110 shown in FIG. 8G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 shown in FIG. 8H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Aligning the positions of the subpixels in the upper row and the lower row as shown in FIG. 8H enables dust and the like that would be produced in the manufacturing process to be removed efficiently. Thus, a display device with high display quality can be provided.

FIG. 8I shows an example where one pixel 110 is composed of three rows and two columns.

The pixel 110 shown in FIG. 8I includes the subpixel 110a in the upper row (first row), the subpixel 110b in the center row (second row), the subpixel 110c across the first row and the second row, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 shown in FIG. 8A to FIG. 8I are each composed of four subpixels: the subpixel 110a, the subpixel 110b, the subpixel 110c, and the subpixel 110d.

The subpixels 110a, 110b, 110c, and 110d can include light-emitting devices that emit light of different colors. The subpixels 110a, 110b, 110c, and 110d can be subpixels of four colors of R, G, B, and white (W), subpixels of four colors of R, G, B, and Y, or subpixels of R, G, B, and infrared light (IR), for example.

In each of the pixels 110 shown in FIG. 8A to FIG. 8I, it is preferable that the subpixel 110a be the subpixel R that emits red light, the subpixel 110b be the subpixel G that emits green light, the subpixel 110c be the subpixel B that emits blue light, and the subpixel 110d be any of a subpixel W that emits white light, a subpixel Y that emits yellow light, and a subpixel IR that emits near-infrared light, for example. In the case of such a structure, stripe arrangement is employed as the layout of R, G, and B in the pixels 110 shown in FIG. 8G and FIG. 8H, leading to higher display quality. In the pixel 110 shown in FIG. 8I, what is called S-stripe arrangement is employed as the layout of R, G, and B, leading to higher display quality.

As described above, the pixel composed of the subpixels each including the light-emitting device can employ any of a variety of layouts in the display device of one embodiment of the present invention.

This embodiment can be combined with any of the other embodiments as appropriate.

### Embodiment 4

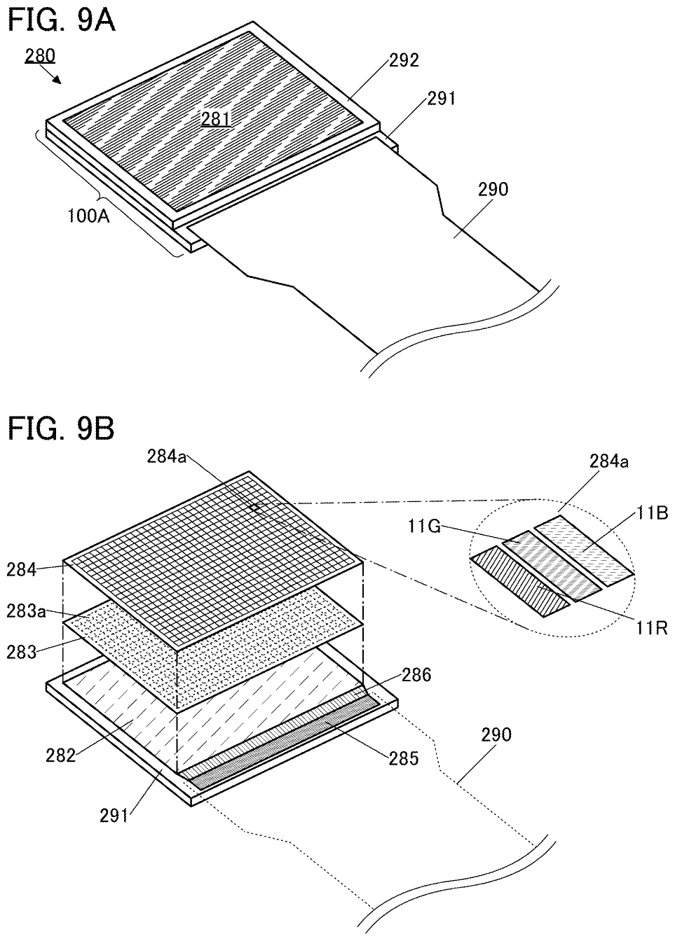

In this embodiment, a display device of one embodiment of the present invention will be described with reference to FIG. 9 to FIG. 18.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display device of this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Module]

FIG. 9A shows a perspective view of a display module 280. The display module 280 includes a display device 100A and an FPC 290. Note that the display device included in the display module 280 is not limited to the display device 100A and may be any of a display device 100B to a display device 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 9B shows a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is shown on the right side of FIG. 9B. The pixel 284a can employ any of the structures described in the above embodiments. FIG. 9B shows an example in which a structure similar to that of the pixel 110 shown in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each controlling light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### [Display Device 100A]

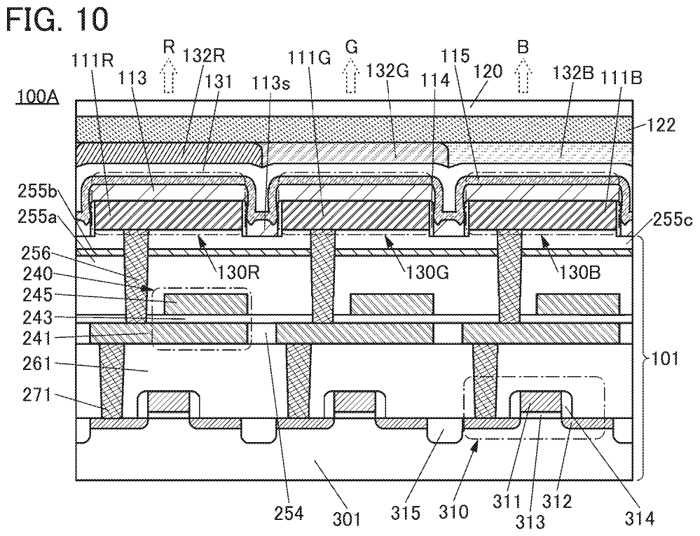

The display device 100A shown in FIG. 10 includes a substrate 301, the light-emitting device 130R, the light-emitting device 130G, the light-emitting device 130B, the coloring layer 132R, the coloring layer 132G, the coloring layer 132B, a capacitor 240, and a transistor 310.

The subpixel 11R shown in FIG. 9B includes the light-emitting device 130R and the coloring layer 132R, the subpixel 11G includes the light-emitting device 130G and the coloring layer 132G, and the subpixel 11B includes the light-emitting device 130B and the coloring layer 132B. In the subpixel 11R, light emitted from the light-emitting device 130R is extracted as red light (R) to the outside of the display device 100A through the coloring layer 132R. Similarly, in the subpixel 11G, light emitted from the light-emitting device 130G is extracted as green light (G) to the outside of the display device 100A through the coloring layer 132G. In the subpixel 11B, light emitted from the light-emitting device 130B is extracted as blue light (B) to the outside of the display device 100A through the coloring layer 132B.

The substrate 301 corresponds to the substrate 291 in FIG. 9A and FIG. 9B. A stacked-layer structure from the substrate 301 to the insulating layer 255c corresponds to the layer 101 including transistors in Embodiment 1.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101 including transistors. The conductive layer can be referred to as a guard ring. By providing the conductive layer, elements such as a transistor and a light-emitting device can be inhibited from being broken by high voltage application due to ESD (electronic discharge) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting device 130R, the light-emitting device 130G, and the light-emitting device 130B are provided over the insulating layer 255c. FIG. 10 shows an example in which the light-emitting device 130R, the light-emitting device 130G, and the light-emitting device 130B each have a structure similar to the stacked-layer structure shown in FIG. 1B.

The pixel electrode 111R, the pixel electrode 111G, and the pixel electrode 111B are each electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. A surface of the insulating layer 255c that is in contact with the pixel electrode and a surface of the plug 256 that is in contact with the pixel electrode are level or substantially level with each other. A variety of conductive materials can be used for the plugs.

The protective layer 131 is provided over the light-emitting device 130R, the light-emitting device 130G, and the light-emitting device 130B. Over the protective layer 131, the coloring layer 132R is provided in a position overlapping with the light-emitting device 130R, the coloring layer 132G is provided in a position overlapping with the light-emitting device 130G, and the coloring layer 132B is provided in a position overlapping with the light-emitting device 130B. The substrate 120 is bonded onto the coloring layers 132R, 132G, and 132B with the resin layer 122. Embodiment 1 can be referred to for the details of the light-emitting devices and the components thereover up to the substrate 120. The substrate 120 corresponds to the substrate 292 in FIG. 9A.

### [Display Device 100B]

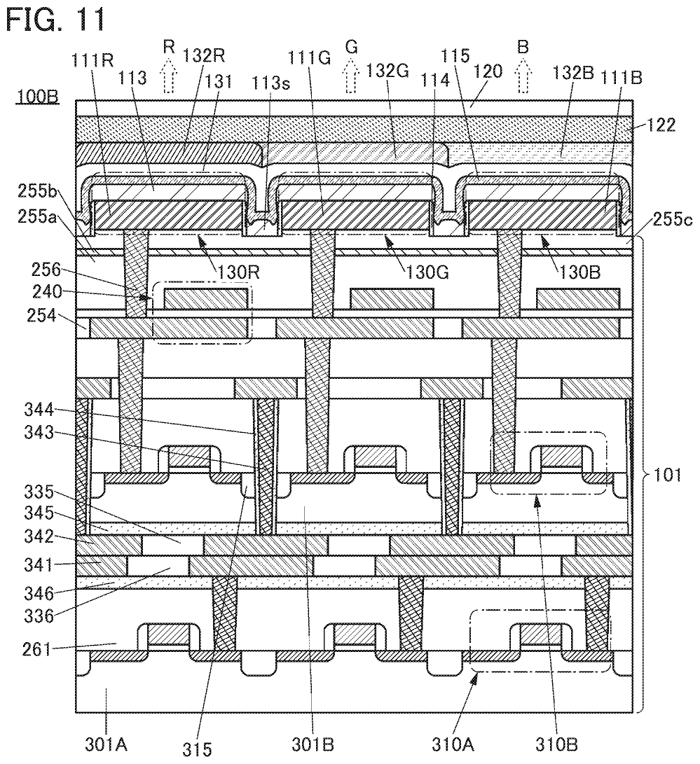

The display device 100B shown in FIG. 11 has a structure in which a transistor 310A and a transistor 310B whose channels are formed in a semiconductor substrate are stacked. Note that in the description of the display device below, portions similar to those of the above-described display device are not described in some cases.

In the display device 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. For the insulating layers 345 and 346, an inorganic insulating film that can be used as the protective layer 131 or an insulating layer 332 can be used.

The substrate 301B is provided with a plug 343 that penetrates the substrate 301B and the insulating layer 345. An insulating layer 344 is preferably provided to cover a side surface of the plug 343. The insulating layer 344 is an insulating layer functioning as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Meanwhile, a conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Device 100C]

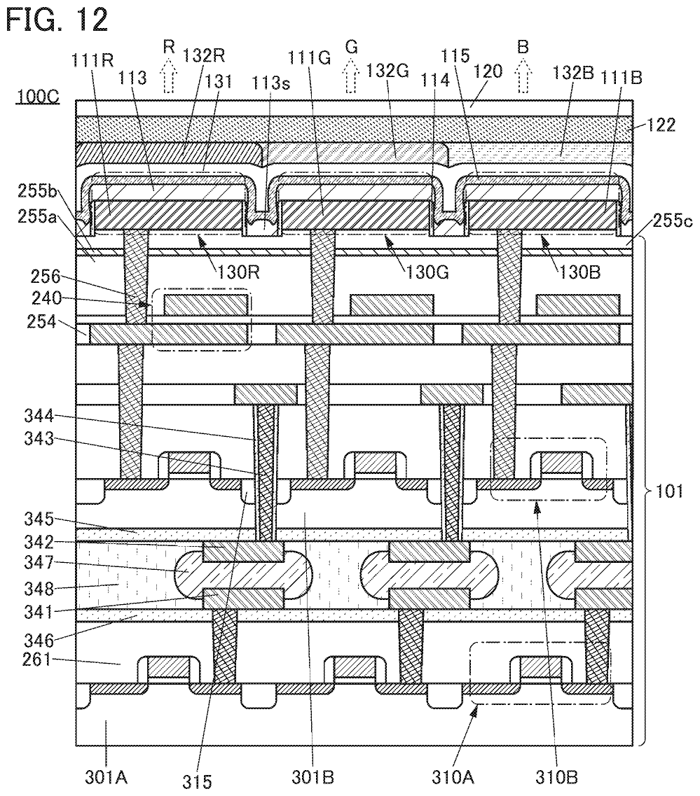

The display device 100C shown in FIG. 12 has a structure in which the conductive layer 341 and the conductive layer 342 are bonded to each other through a bump 347.

As shown in FIG. 12, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 100D]

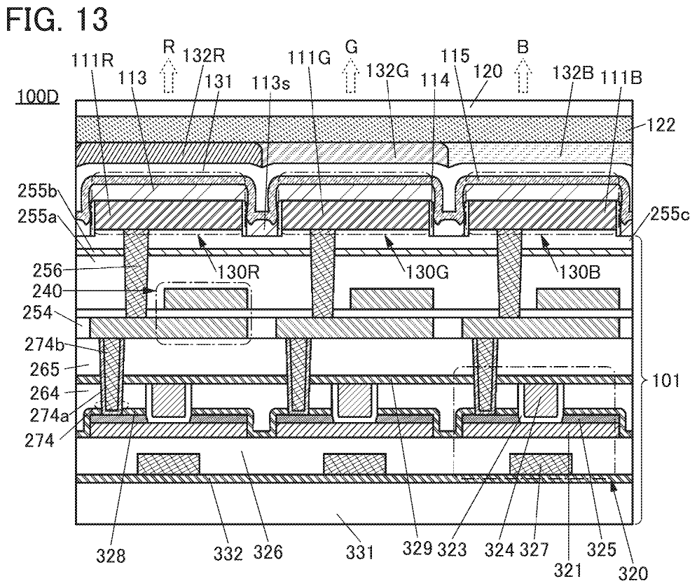

The display device 100D shown in FIG. 13 differs from the display device 100A mainly in a structure of a transistor.

A transistor 320 is a transistor (OS transistor) that includes a metal oxide (also referred to as an oxide semiconductor) in its semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 9A and FIG. 9B. A stacked-layer structure from the substrate 331 to the insulating layer 255c corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide film having semiconductor characteristics (also referred to as an oxide semiconductor). The pair of conductive layers 325 is provided over and in contact with the semiconductor layer 321 and functions as a source electrode and a drain electrode.

An insulating layer 328 is provided to cover top surfaces and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so as to be level or substantially level with each other, and an insulating layer 329 and an insulating layer 265 are provided to cover these layers.

The insulating layer 264 and the insulating layer 265 function as interlayer insulating layers. The insulating layer 329 functions as a barrier layer that prevents diffusion of impurities such as water and hydrogen from the insulating layer 265 or the like into the transistor 320. For the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering a side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Device 100E]

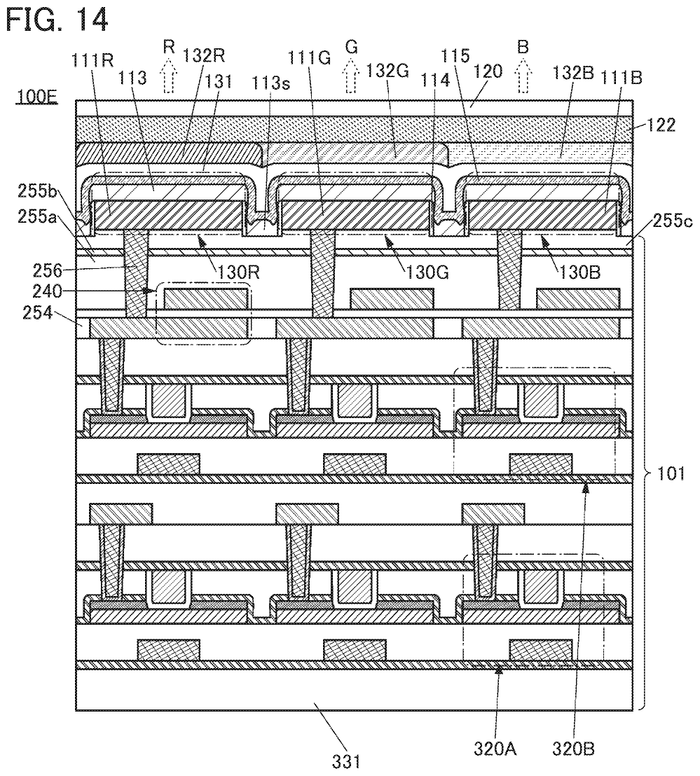

The display device 100E shown in FIG. 14 has a structure in which a transistor 320A and a transistor 320B each including an oxide semiconductor in a semiconductor where a channel is formed are stacked.

The display device 100D can be referred to for the transistor 320A, the transistor 320B, and the components around them.

Although the structure in which two transistors including an oxide semiconductor are stacked is described, the present invention is not limited thereto. For example, three or more transistors may be stacked.

### [Display Device 100F]

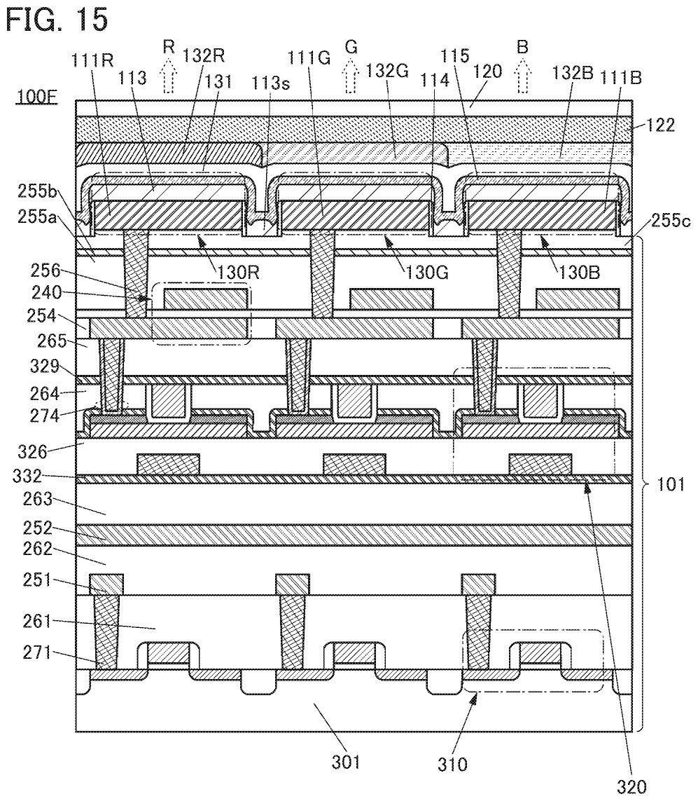

The display device 100F shown in FIG. 15 has a structure in which the transistor 310 having a channel formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display device can be downsized as compared to the case where the driver circuit is provided around a display region.

### [Display Device 100G]

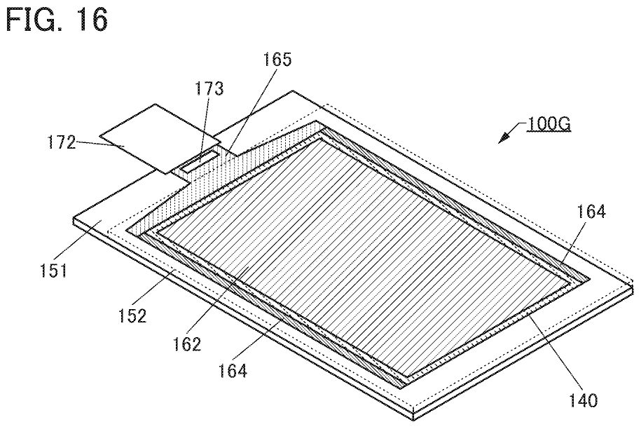

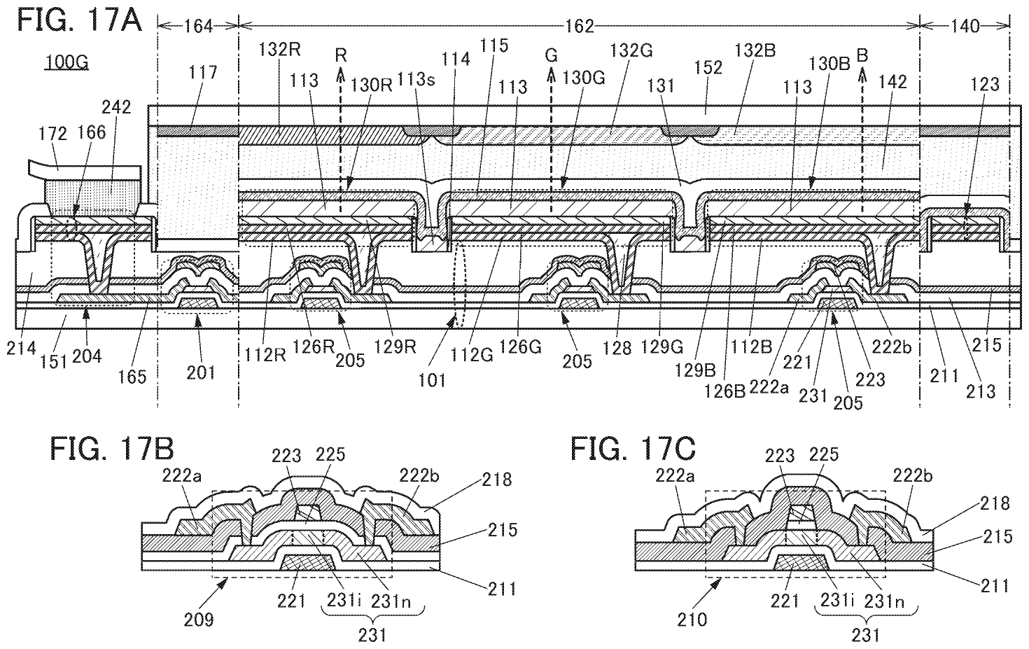

FIG. 16 is a perspective view of a display device 100G, and FIG. 17A is a cross-sectional view of the display device 100G.

In the display device 100G, a substrate 152 and a substrate 151 are bonded to each other. In FIG. 16, the substrate 152 is denoted by a dashed line.

The display device 100G includes a display portion 162, the connection portion 140, a circuit 164, a wiring 165, and the like. FIG. 16 shows an example in which an IC 173 and an FPC 172 are mounted on the display device 100G. Thus, the structure shown in FIG. 16 can also be regarded as a display module including the display device 100G, the IC (integrated circuit), and the FPC.

The connection portion 140 is provided outside the display portion 162. The connection portion 140 can be provided along one or more sides of the display portion 162. The number of the connection portions 140 can be one or more. FIG. 16 shows an example in which the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 16 shows an example in which the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display device 100G and the display module are not necessarily provided with an IC. The IC may be mounted on the FPC by a COF method or the like.

FIG. 17A shows an example of cross sections of part of a region including the FPC 172, part of the circuit 164, part of the display portion 162, part of the connection portion 140, and part of a region including an end portion of the display device 100G.

The display device 100G shown in FIG. 17A includes a transistor 201, a transistor 205, the light-emitting device 130R, the light-emitting device 130G, the light-emitting device 130B, the coloring layer 132R transmitting red light, the coloring layer 132G transmitting green light, the coloring layer 132B transmitting blue light, and the like between the substrate 151 and the substrate 152.

The light-emitting devices 130R, 130G, and 130B each have a structure similar to the stacked-layer structure shown in FIG. 1B except the structure of the pixel electrode. Embodiment 1 can be referred to for the details of the light-emitting devices.

The light-emitting device 130R includes a conductive layer 112R, a conductive layer 126R over the conductive layer 112R, and a conductive layer 129R over the conductive layer 126R. All of the conductive layers 112R, 126R, and 129R can be referred to as pixel electrodes, or one or two of them can be referred to as pixel electrodes.

The light-emitting device 130G includes a conductive layer 112G, a conductive layer 126G over the conductive layer 112G, and a conductive layer 129G over the conductive layer 126G.

The light-emitting device 130B includes a conductive layer 112B, a conductive layer 126B over the conductive layer 112B, and a conductive layer 129B over the conductive layer 126B.

The conductive layer 112R is connected to a conductive layer 222b included in the transistor 205 through an opening provided in an insulating layer 214. It is preferable that the end portion of the conductive layer 112R, the end portion of the conductive layer 126R, and the end portion of the conductive layer 129R be aligned or substantially aligned with each other. Accordingly, the height of the sidewall insulating layer 114 can be equal to or greater than the sum of the thicknesses of the three conductive layers; thus, local thinning of the EL layer or division of the EL layer by the sidewall insulating layer 114 can be facilitated. For example, a conductive layer functioning as a reflective electrode can be used as the conductive layer 112R and the conductive layer 126R, and a conductive layer functioning as a transparent electrode can be used as the conductive layer 129R.

The conductive layers 112G, 126G, and 129G and the conductive layers 112B, 126B, and 129B are similar to the conductive layers 112R, 126R, and 129R; thus, the detailed description is omitted.

The conductive layers 112R, 112G, and 112B are formed to cover the openings provided in the insulating layer 214. A layer 128 is embedded in each of the depressed portions of the conductive layers 112R, 112G, and 112B.

The layer 128 has a function of planarizing the depressed portions of the conductive layers 112R, 112G, and 112B. The conductive layers 126R, 126G, and 126B electrically connected to the conductive layers 112R, 112G, and 112B, respectively, are provided over the conductive layers 112R, 112G, and 112B and the layer 128. Thus, regions overlapping with the depressed portions of the conductive layers 112R, 112G, and 112B can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material.

As the layer 128, an insulating layer containing an organic material can be favorably used. Examples of an organic material that can be used for the layer 128 include organic insulating materials that can be used for the protective layer 131.

The common electrode 115 is provided over the EL layer 113 included in each light-emitting device. The common electrode 115 is a continuous film shared by a plurality of light-emitting devices.

The protective layer 131 is provided over the light-emitting devices 130R, 130G, and 130B. The protective layer 131 and the substrate 152 are bonded to each other with an adhesive layer 142. The substrate 152 is provided with a light-blocking layer 117 and the coloring layers 132R, 132G, and 132B. A solid sealing structure, a hollow sealing structure, or the like can be employed to seal the light-emitting devices. In FIG. 17A, a solid sealing structure is employed in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting device. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit 164. It is also preferable that the protective layer 131 be provided to extend to an end portion of the display device 100G. Meanwhile, a connection portion 204 has a portion not provided with the protective layer 131 so that the FPC 172 and a conductive layer 166 are electrically connected to each other.

The connection portion 204 is provided in a region of the substrate 151 not overlapping with the substrate 152. In the connection portion 204, the wiring 165 is electrically connected to the FPC 172 through the conductive layer 166 and a connection layer 242. In the shown example, the conductive layer 166 has a stacked-layer structure of a conductive film obtained by processing the same conductive film as the conductive layers 112R, 112G, and 112B, a conductive film obtained by processing the same conductive film as the conductive layers 126R, 126G, and 126B, and a conductive film obtained by processing the same conductive film as the conductive layers 129R, 129G, and 129B. On the top surface of the connection portion 204, the conductive layer 166 is exposed. Thus, the connection portion 204 and the FPC 172 can be electrically connected to each other through the connection layer 242.

For example, the protective layer 131 is formed over the entire surface of the display device 100G and then a region of the protective layer 131 overlapping with the conductive layer 166 is removed, so that the conductive layer 166 can be exposed.

A stacked-layer structure of at least one organic layer and a conductive layer may be provided over the conductive layer 166, and the protective layer 131 may be provided over the stacked-layer structure. Then, a peeling trigger (a portion that can be a trigger of peeling) may be formed in the stacked-layer structure using a laser or a sharp cutter (e.g., a needle or a utility knife) to selectively remove the stacked-layer structure and the protective layer 131 thereover, so that the conductive layer 166 may be exposed. For example, the protective layer 131 can be selectively removed when an adhesive roller is pressed to the substrate 151 and then moved relatively while being rolled. Alternatively, an adhesive tape may be attached to the substrate 151 and then peeled. Since the adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the EL layer 113, for example. The organic layer may be formed at the same time as the EL layer 113, or may be provided separately. The conductive layer can be formed using the same step and the same material as those for the common electrode 115. An ITO film is preferably formed as the common electrode 115 and the conductive layer, for example. Note that in the case where a stacked-layer structure is used for the common electrode 115, at least one of the layers included in the common electrode 115 is provided as the conductive layer.

The top surface of the conductive layer 166 may be covered with a mask so that the protective layer 131 is not provided over the conductive layer 166. As the mask, a metal mask (area metal mask) or a tape or a film having adhesiveness or attachability may be used. The protective layer 131 is formed while the mask is placed and then the mask is removed, so that the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 214 in the connection portion 140. In the shown example, the conductive layer 123 has a stacked-layer structure of a conductive film obtained by processing the same conductive film as the conductive layers 112R, 112G, and 112B; a conductive film obtained by processing the same conductive film as the conductive layers 126R, 126G, and 126B; and a conductive film obtained by processing the same conductive film as the conductive layers 129R, 129G, and 129B. A side surface of the conductive layer 123 is covered with the sidewall insulating layer 114. The sidewall insulating layer 114 functions as a sidewall of the conductive layer 123. The common electrode 115 is provided over and in contact with the conductive layer 123. That is, in the connection portion 140, the conductive layer 123 and the common electrode 115 are electrically connected to each other.

The display device 100G has a top-emission structure. Light emitted by the light-emitting device is emitted toward the substrate 152 side. For the substrate 152, a material having a high visible-light-transmitting property is preferably used. The pixel electrode contains a material reflecting visible light, and the counter electrode (the common electrode 115) contains a material transmitting visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers that cover the transistors. This allows the insulating layer to function as a barrier layer. Such a structure can effectively inhibit diffusion of impurities into the transistors from the outside and improve the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a depressed portion can be inhibited from being formed in the insulating layer 214 in processing the conductive layer 112R, the conductive layer 126R, the conductive layer 129R, or the like. Alternatively, a depressed portion may be provided in the insulating layer 214 in processing the conductive layer 112R, the conductive layer 126R, the conductive layer 129R, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or bottom-gate transistor structure may be employed. Alternatively, gates may be provided above and below the semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The semiconductor layer of the transistor preferably contains a metal oxide (also referred to as an oxide semiconductor). That is, a transistor including a metal oxide in its channel formation region (hereinafter, referred to as an OS transistor) is preferably used for the display device of this embodiment.

As the oxide semiconductor having crystallinity, a CAAC (c-axis aligned crystalline)-OS, an nc (nanocrystalline)-OS, and the like are given.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistor such as an LTPS transistor, a circuit required to be driven at a high frequency (e.g., a source driver circuit) can be formed on the same substrate as the display portion. This allows simplification of an external circuit mounted on the display device and a reduction in component cost and mounting cost.

An OS transistor has much higher field-effect mobility than a transistor using amorphous silicon. In addition, an OS transistor has an extremely low leakage current between a source and a drain in an off state (hereinafter also referred to as off-state current), and charge accumulated in a capacitor that is connected in series to the transistor can be retained for a long period. Furthermore, the power consumption of the display device can be reduced with the OS transistor.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be fed through the OS transistor than through a Si transistor. Thus, by using an OS transistor as the driving transistor, a stable current can be fed through the light-emitting device even when the current-voltage characteristics of the EL device vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black floating”, “increase in emission luminance”, “increase in the number of gray levels”, “inhibition of variation in light-emitting devices”, and the like.

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, in the case where the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, in the case where the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, in the case where the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistors included in the circuit 164 and the transistors included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, can be given.

For example, one transistor included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

In contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML (metal maskless) structure. This structure can significantly reduce the leakage current that might flow through a transistor, and the leakage current that might flow between adjacent light-emitting devices (also referred to as a lateral leakage current, a side leakage current, or the like). With the structure, a viewer can observe any one or more of image crispness, image sharpness, a high chroma, and a high contrast ratio in an image displayed on the display device. Note that when the leakage current that might flow through a transistor and the lateral leakage current between light-emitting devices are extremely low, light leakage or the like (what is called black blurring) that might occur in black display can be reduced as much as possible.

FIG. 17B and FIG. 17C show other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 17B shows an example of the transistor 209 in which the insulating layer 225 covers the top surface and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 shown in FIG. 17C, the insulating layer 225 overlaps with the channel formation region 231i of the semiconductor layer 231 and does not overlap with the low-resistance regions 231n. The structure shown in FIG. 17C can be fabricated by processing the insulating layer 225 using the conductive layer 223 as a mask, for example. In FIG. 17C, the insulating layer 215 is provided to cover the insulating layer 225 and the conductive layer 223, and the conductive layer 222a and the conductive layer 222b are connected to the low-resistance regions 231n through the openings in the insulating layer 215.

The light-blocking layer 117 is preferably provided on the surface of the substrate 152 that faces the substrate 151. The light-blocking layer 117 can be provided between adjacent light-emitting devices, in the connection portion 140, and in the circuit 164, for example. A variety of optical members can be arranged on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### [Display Device 100H]

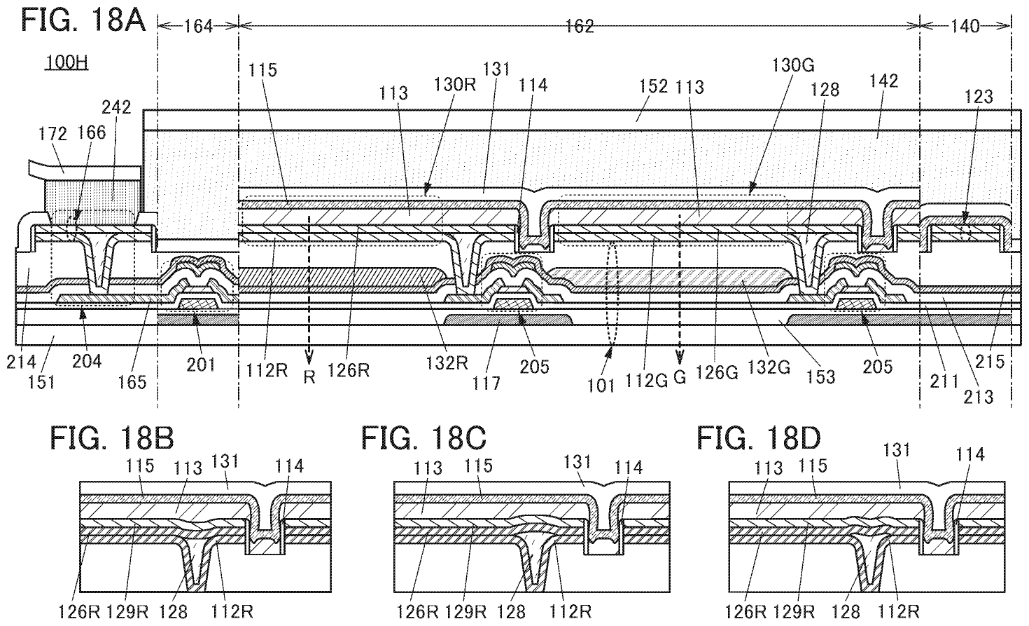

A display device 100H shown in FIG. 18A is different from the display device 100G mainly in being a bottom-emission display device.

Light emitted by the light-emitting device is emitted toward the substrate 151 side. For the substrate 151, a material having a high visible-light-transmitting property is preferably used. In contrast, there is no limitation on the light-transmitting property of a material used for the substrate 152.

The light-blocking layer 117 is preferably formed between the substrate 151 and the transistor 201 and between the substrate 151 and the transistor 205. FIG. 18A shows an example in which the light-blocking layer 117 is provided over the substrate 151, an insulating layer 153 is provided over the light-blocking layer 117, and the transistors 201 and 205 and the like are provided over the insulating layer 153. The coloring layer 132R and the coloring layer 132G are provided over the insulating layer 215.

The light-emitting device 130R includes the conductive layer 112R and the conductive layer 126R over the conductive layer 112R.

The light-emitting device 130G includes the conductive layer 112G and the conductive layer 126G over the conductive layer 112G.

A material having a high visible-light-transmitting property is preferably used for each of the conductive layers 112R, 112G, 126R, and 126G. A material reflecting visible light is preferably used for the common electrode 115.

Although FIG. 17A, FIG. 18A, and the like show an example in which the top surface of the layer 128 includes a flat portion, the shape of the layer 128 is not particularly limited. FIG. 18B to FIG. 18D show variation examples of the layer 128.

As shown in FIG. 18B and FIG. 18D, the top surface of the layer 128 can have a shape such that its center and the vicinity thereof are depressed, i.e., a shape including a concave surface, in a cross-sectional view.

As shown in FIG. 18C, the top surface of the layer 128 can have a shape such that its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 112R may be equal to or substantially equal to each other, or may be different from each other. For example, the level of the top surface of the layer 128 may be either lower or higher than the level of the top surface of the conductive layer 112R.

FIG. 18B can be regarded as illustrating an example in which the layer 128 fits in the depressed portion of the conductive layer 112R. By contrast, as shown in FIG. 18D, the layer 128 may exist also outside the depressed portion of the conductive layer 112R, that is, the layer 128 may be formed to have the top surface wider than the depressed portion.

This embodiment can be combined with the other embodiments as appropriate.

### Embodiment 5

In this embodiment, a light-emitting device that can be used in the display device of one embodiment of the present invention will be described.

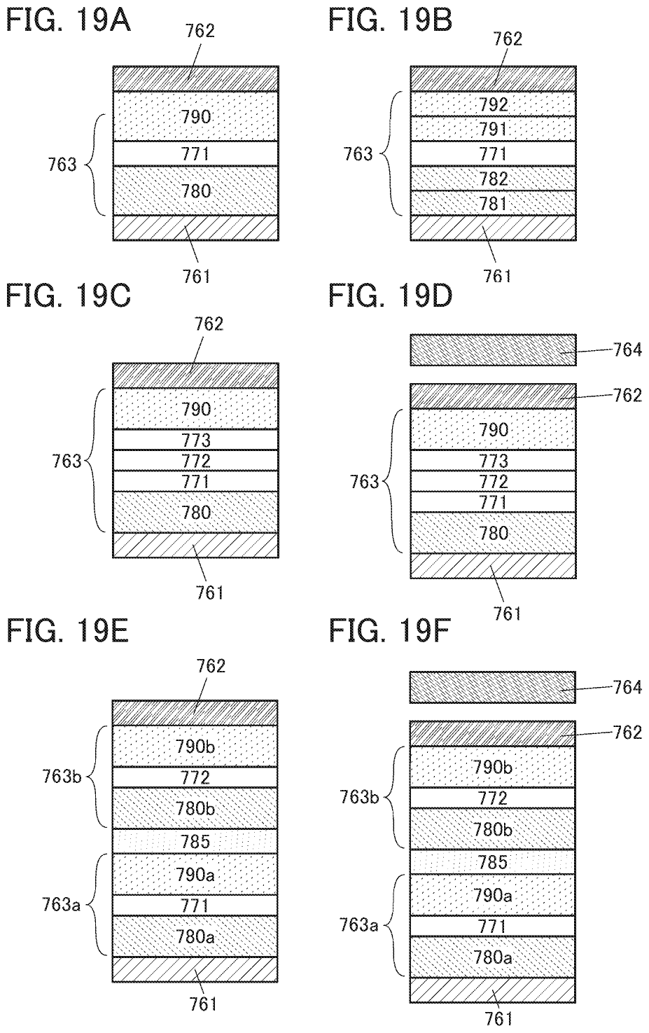

As shown in FIG. 19A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 19A is referred to as a single structure in this specification.

FIG. 19B is a modification example of the EL layer 763 included in the light-emitting device shown in FIG. 19A. Specifically, the light-emitting device shown in FIG. 19B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that as shown in FIG. 19C and FIG. 19D, structures in which a plurality of light-emitting layers (light-emitting layers 771, 772, and 773) are provided between the layer 780 and the layer 790 are other variations of the single structure. Although FIG. 19C and FIG. 19D show the examples where three light-emitting layers are included, the light-emitting device having a single structure may include two or four or more light-emitting layers. In addition, the light-emitting device having a single structure may include a buffer layer between two light-emitting layers. The buffer layer can be formed using a material that can be used for the hole-transport layer or the electron-transport layer, for example.

A structure where a plurality of light-emitting units (a light-emitting unit 763a and a light-emitting unit 763b) are connected in series with a charge-generation layer 785 (also referred to as an intermediate layer) therebetween as shown in FIG. 19E and FIG. 19F is referred to as a tandem structure in this specification. Note that a tandem structure may be referred to as a stack structure. The tandem structure enables a light-emitting device capable of high-luminance light emission. Furthermore, the tandem structure reduces the amount of current needed for obtaining the same luminance as compared with a single structure, and thus can improve the reliability.

Note that FIG. 19D and FIG. 19F are examples where the display device includes a layer 764 overlapping with the light-emitting device. FIG. 19D is an example where the layer 764 overlaps with the light-emitting device shown in FIG. 19C, and FIG. 19F is an example where the layer 764 overlaps with the light-emitting device shown in FIG. 19E. In FIG. 19D and FIG. 19F, light is extracted from the upper electrode 762 side, so that a conductive film that transmits visible light is used as the upper electrode 762.

One or both of a color conversion layer and a color filter (a coloring layer) can be used as the layer 764.

In FIG. 19C and FIG. 19D, light-emitting substances that emit light of different colors can be used for the light-emitting layer 771, the light-emitting layer 772, and the light-emitting layer 773. White light emission can be obtained when the light-emitting layer 771, the light-emitting layer 772, and the light-emitting layer 773 emit light of complementary colors. The light-emitting device having a single structure preferably includes a light-emitting layer containing a light-emitting substance that emits blue light and a light-emitting layer containing a light-emitting substance that emits visible light with a longer wavelength than blue light, for example.

A color filter is preferably provided as the layer 764 shown in FIG. 19D. When white light passes through the color filter, light of a desired color can be obtained.

In the case where the light-emitting device having a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be R, G, and B or R, B, and G from an anode side, for example. In that case, a buffer layer may be provided between R and G or between R and B.

In the case where the light-emitting device having a single structure includes two light-emitting layers, for example, a light-emitting layer containing a light-emitting substance that emits blue (B) light and a light-emitting layer containing a light-emitting substance that emits yellow (Y) light are preferably included. Such a structure may be referred to as a BY single structure.

The light-emitting device that emits white light preferably contains two or more kinds of light-emitting substances. In order to obtain white light emission, light-emitting substances may be selected so that colors of light emitted by the two light-emitting substances are complementary colors, or light-emitting substances may be selected so that colors of light emitted by two or more light-emitting substances are combined to be white. For example, in the case where white light emission is obtained with use of two light-emitting layers, light-emitting substances are selected so that the emission colors of the two light-emitting layers are complementary colors. For example, when an emission color of a first light-emitting layer and an emission color of a second light-emitting layer are complementary colors, the light-emitting device can emit white light as a whole. In the case where three or more light-emitting layers are used to obtain white light emission, a light-emitting device is configured to emit white light as a whole by combining emission colors of the three or more light-emitting layers.

Note that also in FIG. 19C and FIG. 19D, the layer 780 and the layer 790 may each independently have a stacked-layer structure of two or more layers as shown in FIG. 19B.

In FIG. 19E and FIG. 19F, light-emitting substances that emit light of different colors can be used for the light-emitting layer 771 and the light-emitting layer 772. White light emission can be obtained when the light-emitting layer 771 and the light-emitting layer 772 emit light of complementary colors. A color filter is preferably provided as the layer 764 shown in FIG. 19F. When white light passes through the color filter, light of a desired color can be obtained.

Although FIG. 19E and FIG. 19F show examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 19E and FIG. 19F each show the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 19E and FIG. 19F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

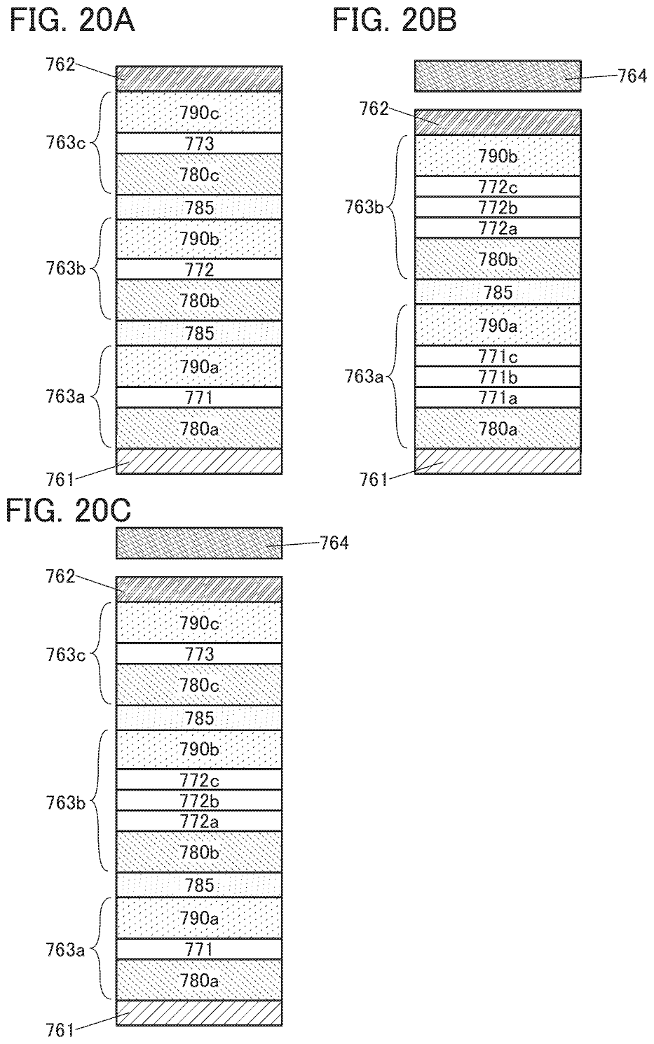

Structures shown in FIG. 20A to FIG. 20C are given as examples of a light-emitting device having a tandem structure.

FIG. 20A shows a structure including three light-emitting units. As shown in FIG. 20A, a plurality of light-emitting units (the light-emitting unit 763a, the light-emitting unit 763b, and a light-emitting unit 763c) are connected in series through charge-generation layers 785. The light-emitting unit 763a includes the layer 780a, the light-emitting layer 771, and the layer 790a, the light-emitting unit 763b includes the layer 780b, the light-emitting layer 772, and the layer 790b, and the light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 20A, light-emitting substances that emit light of different colors can be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

FIG. 20B shows a tandem light-emitting device in which light-emitting units each including a plurality of light-emitting layers are stacked. FIG. 20B shows a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a, and the light-emitting unit 763b includes the layer 780b, a light-emitting layer 772a, a light-emitting layer 772b, a light-emitting layer 772c, and the layer 790b.

In the structure shown in FIG. 20B, the light-emitting unit 763a is configured to emit white (W) light by selecting light-emitting substances so that the emission colors of the light-emitting layer 771a, the light-emitting layer 771b, and the light-emitting layer 771c are complementary colors. Furthermore, the light-emitting unit 763b is configured to emit white (W) light by selecting light-emitting substances so that the emission colors of the light-emitting layer 772a, the light-emitting layer 772b, and the light-emitting layer 772c are complementary colors. That is, the structure shown in FIG. 20B is a two-unit tandem structure of W\W. Note that there is no particular limitation on the stacking order of the light-emitting substances that emit light of complementary colors. The practitioner can select the optimal stacking order as appropriate. Although not illustrated, a three-unit tandem structure of W\W\W or a tandem structure with four or more units may be employed. Note that “a\b” means that a light-emitting unit containing a light-emitting substance that emits light of b is provided over a light-emitting unit containing a light-emitting substance that emits light of a with a charge-generation layer therebetween, where a and b represent colors.

In the case of a light-emitting device with a tandem structure, any of the following structure may be employed, for example: a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\Y\G\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a-b” means that one light-emitting unit contains a light-emitting substance that emits light of a and a light-emitting substance that emits light of b.

Alternatively, a light-emitting unit including one light-emitting layer and a light-emitting unit including a plurality of light-emitting layers may be used in combination as shown in FIG. 20C.

Specifically, in the structure shown in FIG. 20C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a, the light-emitting unit 763b includes a layer 780b, the light-emitting layer 772a, the light-emitting layer 772b, the light-emitting layer 772c, and the layer 790b, and the light-emitting unit 763c includes the layer 780c, the light-emitting layer 773, and the layer 790c.

As the structure shown in FIG. 20C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used as the electrode through which light is extracted, which is either the lower electrode 761 or the upper electrode 762. A conductive film that reflects visible light is preferably used for the electrode through which light is not extracted. In the case where a display device includes a light-emitting device that emits infrared light, a conductive film transmitting visible light and infrared light is preferably used as the electrode through which light is extracted, and a conductive film reflecting visible light and infrared light is preferably used as the electrode through which light is not extracted.

A conductive film transmitting visible light may be used also for the electrode through which light is not extracted. In this case, this electrode is preferably provided between the reflective layer and the EL layer 763. In other words, light emitted from the EL layer 763 may be reflected by the reflective layer to be extracted from the display device.

As a material that forms a pair of electrodes of the light-emitting device, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Accordingly, one of the pair of electrodes of the light-emitting device preferably includes an electrode having a transmitting property and a reflecting property with respect to visible light (transflective electrode), and the other preferably includes an electrode having a reflecting property with respect to visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer having a visible-light-transmitting property (also referred to as a transparent electrode).

The light transmittance of the transparent electrode is higher than or equal to 40%. For example, an electrode having a visible light (light with wavelengths greater than or equal to 400 nm and less than 750 nm) transmittance higher than or equal to 40% is preferably used in the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron-transport property and a high hole-transport property, also referred to as a bipolar material), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be contained. Each layer included in the light-emitting device can be formed, for example, by an evaporation method (including a vacuum evaporation method), a transfer method, a printing method, an inkjet method, or a coating method.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a substance with a high hole-transport property which can be used for the hole-transport layer and will be described later. As the electron-transport material, it is possible to use a substance having a high electron-transport property which can be used for the electron-transport layer and will be described later. Alternatively, as one or more kinds of organic compounds, a bipolar material or a TADF material may be used.

The light-emitting layer preferably contains, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer that injects holes from an anode to the hole-transport layer and contains a substance with a high hole-injection property. Examples of the substance with a high hole-injection property include an aromatic amine compound and a composite material containing a hole-transport material and an acceptor material (electron-accepting material).

As the hole-transport material, it is possible to use a substance with a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can also be used.

For example, a hole-transport material and a material containing an oxide of a metal belonging to Group 4 to Group 8 of the periodic table (typically, molybdenum oxide) may be used as the substance having a high hole-injection property.

The hole-transport layer is a layer transporting holes, which are injected from the anode by the hole-injection layer, to the light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, substances with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a substance with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

The difference between the LUMO level of the substance with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a substance having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can inhibit an increase in driving voltage.

This embodiment can be combined with the other embodiments as appropriate.

### Embodiment 6

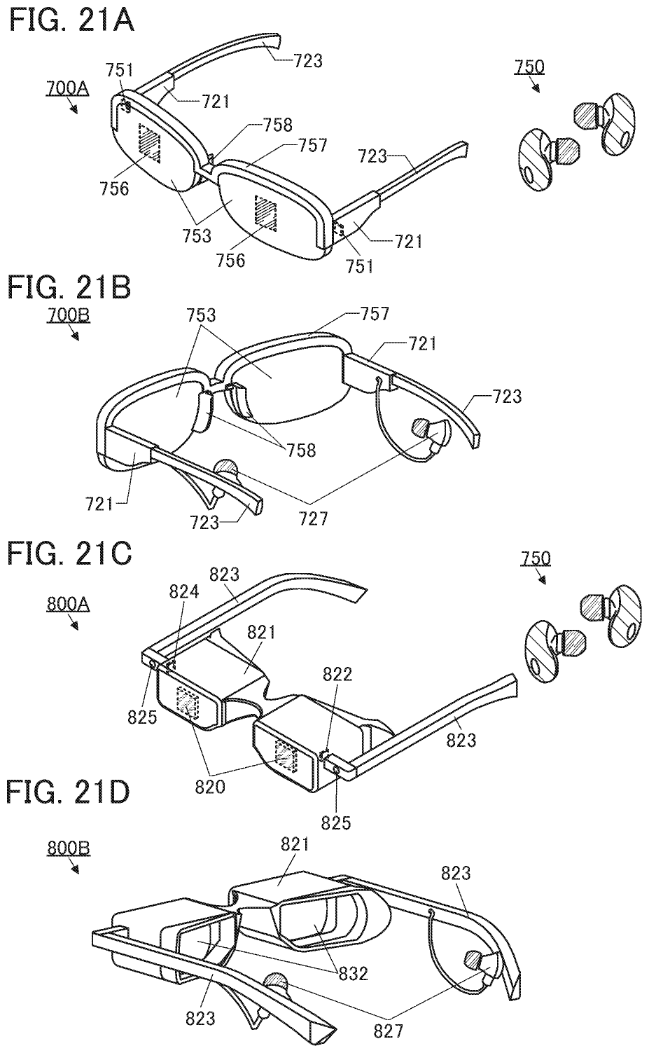

In this embodiment, electronic devices of one embodiment of the present invention will be described with reference to FIG. 21 to FIG. 23.

Electronic devices in this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display device of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. By using the display device having one or both of such high definition and high resolution, the electronic device can have more improved realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head are described with reference to FIG. 21A to FIG. 21D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A shown in FIG. 21A and an electronic device 700B shown in FIG. 21B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A shown in FIG. 21C and an electronic device 800B shown in FIG. 21D each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of the display portions 820 displays different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 21C and the like show examples where the wearing portion has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A shown in FIG. 21A has a function of transmitting information to the earphones 750 with the wireless communication function. As another example, the electronic device 800A shown in FIG. 21C has a function of transmitting information to the earphones 750 with the wireless communication function.

The electronic device may include an earphone portion. The electronic device 700B shown in FIG. 21B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B shown in FIG. 21D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. The earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

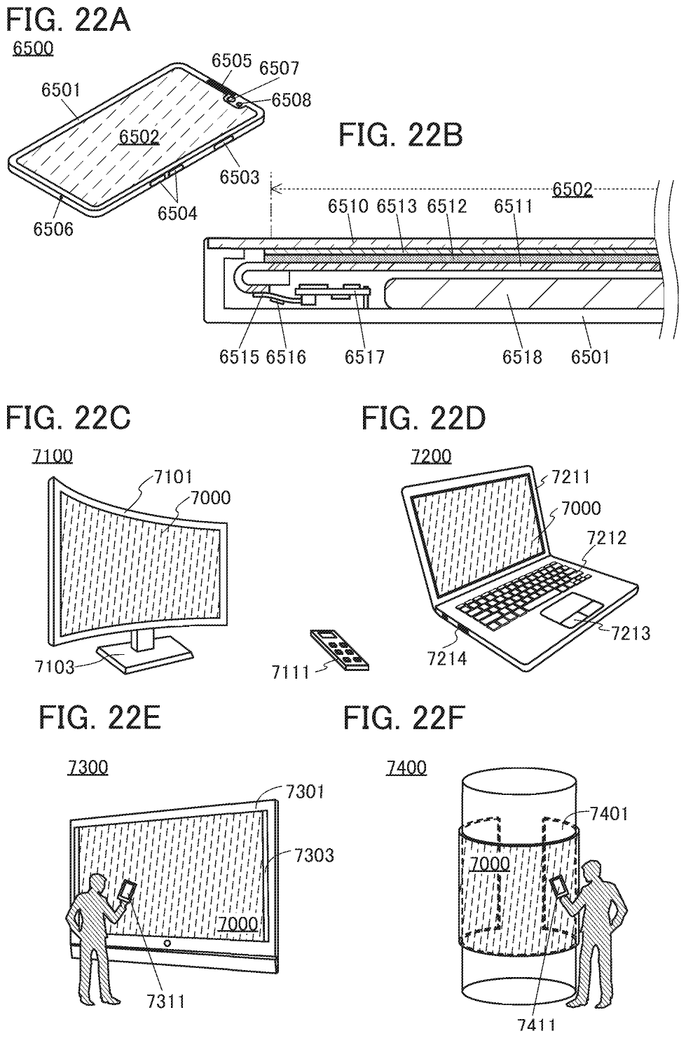

An electronic device 6500 shown in FIG. 22A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 22B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while an increase in thickness of the electronic device is suppressed. Moreover, part of the display panel 6511 is folded back so that a connection portion with the FPC 6515 is provided on the back side of the pixel portion, whereby an electronic device with a narrow bezel can be achieved.

FIG. 22C shows an example of a television device. In a television device 7100, a display portion 7000 is incorporated in a housing 7101. Here, a structure in which the housing 7101 is supported by a stand 7103 is shown.

The display device of one embodiment of the present invention can be used for the display portion 7000.

Operation of the television device 7100 shown in FIG. 22C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 22D shows an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 22E and FIG. 22F show examples of digital signage.

Digital signage 7300 shown in FIG. 22E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 22F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in each of FIG. 22E and FIG. 22F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As shown in FIG. 22E and FIG. 22F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

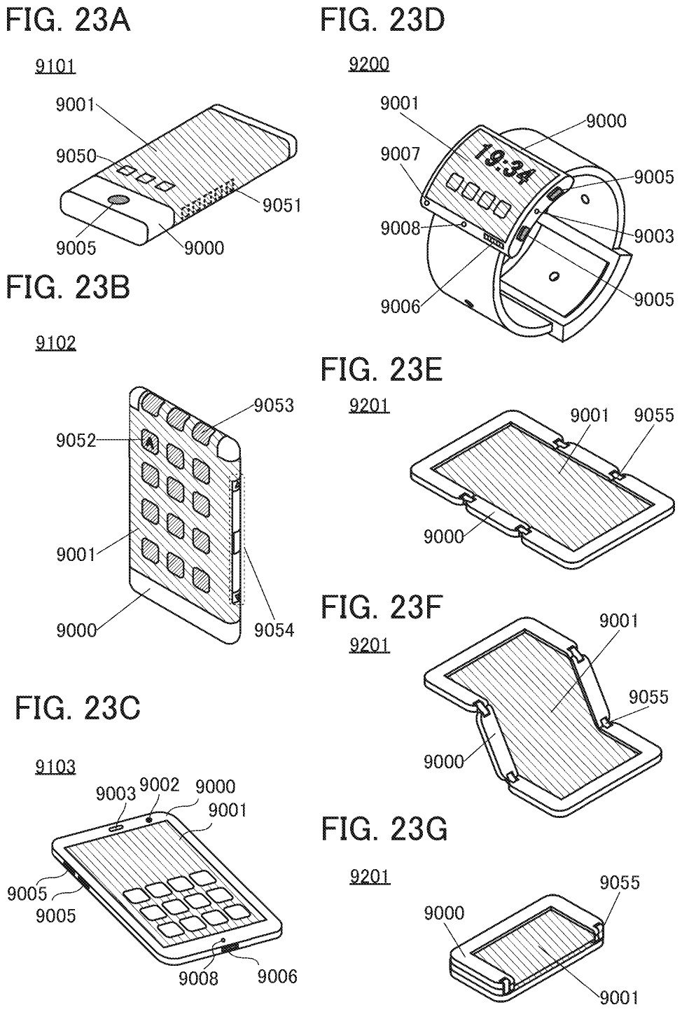

Electronic devices shown in FIG. 23A to FIG. 23G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 23A to FIG. 23G.

The electronic devices shown in FIG. 23A to FIG. 23G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices shown in FIG. 23A to FIG. 23G are described in detail below.

FIG. 23A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 23A shows an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 23B is a perspective view illustrating a portable information terminal 9102. The portable information terminal 9102 has a function of displaying information on three or more surfaces of the display portion 9001. Shown here is an example in which information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 23C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 23D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 23E to FIG. 23G are perspective views illustrating a foldable portable information terminal 9201. FIG. 23E is a perspective view of an opened state of the portable information terminal 9201, FIG. 23G is a perspective view of a folded state thereof, and FIG. 23F is a perspective view of a state in the middle of change from one of FIG. 23E and FIG. 23G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

11B: subpixel, 11G: subpixel, 11R: subpixel, 100A: display device, 100B: display device, 100C: display device, 100D: display device, 100E: display device, 100F: display device, 100G: display device, 100H: display device, 100: display device, 101: layer, 110a: subpixel, 110b: subpixel, 110c: subpixel, 110d: subpixel, 110: pixel, 111B: pixel electrode, 111G: pixel electrode, 111R: pixel electrode, 112B: conductive layer, 112G: conductive layer, 112R: conductive layer, 113s: material layer, 113t: region, 113: EL layer, 114A: insulating film, 114: sidewall insulating layer, 115: common electrode, 116B: optical adjustment layer, 116G: optical adjustment layer, 116R: optical adjustment layer, 117: light-blocking layer, 120: substrate, 122: resin layer, 123: conductive layer, 124a: pixel, 124b: pixel, 126B: conductive layer, 126G: conductive layer, 126R: conductive layer, 128: layer, 129B: conductive layer, 129G: conductive layer, 129R: conductive layer, 130B: light-emitting device, 130G: light-emitting device, 130R: light-emitting device, 131: protective layer, 132B: coloring layer, 132G: coloring layer, 132R: coloring layer, 133: lens array, 134: insulating layer, 140: connection portion, 142: adhesive layer, 150A: region, 150B: region, 150C: region, 150D: region, 150E: region, 150F: region, 151: substrate, 152: substrate, 153: insulating layer, 162: display portion, 164: circuit, 165: wiring, 166: conductive layer, 172: FPC, 173: IC, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first light-emitting device;
a second light-emitting device;
an insulating layer;
a first sidewall insulating layer;
a second sidewall insulating layer;
a first coloring layer; and
a second coloring layer,
wherein the first light-emitting device comprises a first pixel electrode over the insulating layer, a first layer over the first pixel electrode, and a common electrode over the first layer,
wherein the second light-emitting device comprises a second pixel electrode over the insulating layer, the first layer over the second pixel electrode, and the common electrode over the first layer,
wherein the first sidewall insulating layer is in contact with a side surface of the first pixel electrode,
wherein the second sidewall insulating layer is in contact with a side surface of the second pixel electrode,
wherein the first coloring layer overlaps with the first light-emitting device,
wherein the second coloring layer overlaps with the second light-emitting device,
wherein the second coloring layer and the first coloring layer are configured to transmit light of different colors,
wherein the first layer comprises a first light-emitting material and a second light-emitting material,
wherein the first light-emitting material is configured to emit blue light,
wherein the second light-emitting material is configured to emit light with a longer wavelength than blue light, and
wherein the first layer comprises a portion in contact with a top surface of the insulating layer between the first sidewall insulating layer and the second sidewall insulating layer.

2.-4. (canceled)

5. The display device according to claim 1,
wherein the first sidewall insulating layer is further in contact with a side surface and the top surface of the insulating layer, and
wherein the second sidewall insulating layer is further in contact with a side surface and the top surface of the insulating layer.

6. The display device according to claim 1,
wherein the shortest distance between the first sidewall insulating layer and the second sidewall insulating layer is less than 10 μm.

7. The display device according to claim 1,
wherein the shortest distance between the first sidewall insulating layer and the second sidewall insulating layer is less than or equal to 1 μm.

8. The display device according to claim 1,
wherein the first sidewall insulating layer comprises an inorganic insulating material.

9.-10. (canceled)

11. A method for fabricating a display device, comprising:
forming a conductive film over an insulating surface;
processing the conductive film to form a first pixel electrode and a second pixel electrode;
forming an insulating film covering the first pixel electrode and the second pixel electrode;
processing the insulating film to form a first sidewall insulating layer in contact with a side surface of the first pixel electrode and a second sidewall insulating layer in contact with a side surface of the second pixel electrode and to expose a top surface of the first pixel electrode and a top surface of the second pixel electrode;
forming a first layer in contact with the top surface of the first pixel electrode, the top surface of the second pixel electrode, and the insulating surface;
forming a common electrode in contact with the first layer; and
arranging a first coloring layer overlapping with the first pixel electrode and a second coloring layer overlapping with the second pixel electrode over the common electrode,
wherein the first layer comprises a first light-emitting material and a second light-emitting material,
wherein the first light-emitting material is configured to emit blue light, and
wherein the second light-emitting material is configured to emit light with a longer wavelength than blue light.

12. A method for fabricating a display device, comprising:
forming a conductive film over an insulating surface;
processing the conductive film to form a first pixel electrode and a second pixel electrode;
forming an insulating film covering the first pixel electrode and the second pixel electrode;
processing the insulating film to form a first sidewall insulating layer in contact with a side surface of the first pixel electrode and a second sidewall insulating layer in contact with a side surface of the second pixel electrode and to expose a top surface of the first pixel electrode and a top surface of the second pixel electrode;
forming a first layer in contact with the top surface of the first pixel electrode, a second layer in contact with the top surface of the second pixel electrode, and a material layer in contact with the insulating surface in the same step;
forming a common electrode in contact with the first layer and the second layer; and
arranging a first coloring layer overlapping with the first pixel electrode and a second coloring layer overlapping with the second pixel electrode over the common electrode.

13. The method for fabricating a display device, according to claim 12,
wherein the first layer comprises a first light-emitting material and a second light-emitting material,
wherein the first light-emitting material is configured to emit blue light, and
wherein the second light-emitting material is configured to emit light with a longer wavelength than blue light.

14. The method for fabricating a display device, according to claim 12,
wherein the common electrode is in contact with the material layer.
